(19) United States
(12) Patent Application Publication
(10) Pub. No.: US 2002/0111024 A1
(43) Pub. Date: Aug. 15, 2002

(54) Chemical mechanical polishing compositions

(76) Inventors: Robert J. Small, Dublin, CA (US); Laurence McGhee, Glasgow (GB); David J. Maloney, Pleasanton, CA (US); Maria L. Peterson, Belmont, CA (US)

Correspondence Address: PENNIE & EDMONDS LLP, 1667 K STREET NW, SUITE 1000, WASHINGTON, DC, 20006

(21) Appl. No.: 09/985,870

(22) Filed: Nov. 6, 2001

Related U.S. Application Data
(63) Continuation-in-part of application No. 09/481,050, filed on Jan. 11, 2000.
Application No. 09/481,050 is a continuation of application No. 09/043,505, filed on Mar. 23, 1998.
Application No. 09/043,505 is a 371 of international application No. PCT/US97/12220, filed on Jul. 21, 1997.
(60) Provisional application No. 60/023,299, filed on Jul. 26, 1996.

(51) Int. Cl. H01L 21/302; H01L 21/461

(52) U.S. Cl. 438/689

(57) ABSTRACT

A composition for chemical mechanical polishing that includes a slurry is described. A sufficient amount of a selectively oxidizing and reducing compound is provided to produce a differential removal of a metal and a dielectric material. A pH adjusting compound adjusts the pH of the composition to provide a pH that makes the selectively oxidizing and reducing compound provide the differential removal of a metal and a dielectric material. A composition may include an effective amount of an hydroxylamine compound, ammonium persulfate, a compound which is an indirect source of hydrogen peroxide, and a peracetic acid or periodic acid. A method for chemical mechanical polishing is described which includes applying a slurry that includes the composition to a surface to produce mechanical removal of the metal and dielectric material.

### CROSS-REFERENCE TO RELATED APPLICATIONS

This application is a continuation-in-part of pending U.S. application Ser. No. 09/481,050, filed Jan. 11, 2000, now U.S. Pat. No. 6,313,039 issued Nov. 6, 2001, which is a continuation application of U.S. application Ser. No. 09/043,505 filed Mar. 23, 1998, which is a 371 filing of International Application No. PCT/US97/12220 filed Jul. 21, 1997, which claims priority from U.S. Provisional Patent Application Serial No. 60/023,299 filed Jul. 26, 1996, the disclosures of which are incorporated herein by reference thereto.

### FIELD OF THE INVENTION

This invention relates to improved compositions and processes for the chemical mechanical polishing or planarization of semiconductor wafers. More particularly, it relates to such a composition and process that are tailored to meet more stringent requirements of advanced integrated circuit fabrication. More particularly, the present invention relates generally to compositions for chemical mechanical planarization or polishing processes in the manufacture of integrated circuits of a layer arrangement comprised of a copper layer, a tungsten layer, a tantalum and/or a tantalum nitride layer, an aluminum layer, and other specific metal layers and dielectric layers.

### BACKGROUND OF THE INVENTION

Integrated circuits typically comprise a semiconductor substrate and a plurality of patterned dielectric (insulating) and conductive thin films thereon. Modem integrated circuits are made up of millions of active devices strategically interconnected through the use of multilevel interconnections including conductive lines and plugs for forming functional integrated circuits and components. For example, the conductive patterns of adjacent layers are electrically connected through an intervening dielectric (insulating) layer by a conductive interconnect or plug. Similarly, a conductive plug filling a contact opening establishes electrical contact with an active region on the semiconductor substrate, such as a source/drain region.

In the manufacture of integrated circuits, wafer polishing is a common technique utilized to remove material and/or achieve planarity. Such polishing (or planarization) can be conducted by purely chemical, purely mechanical, or by a combination of chemical and mechanical mechanisms. The chemical reactions of the chemical mechanical polishing process alone will not achieve planarization because the chemical actions involved in such processes are isotropic. And while mechanical grinding alone may theoretically achieve the desired planarization, this approach is not desirable because of extensive damage caused to the material surface. Accordingly, a combination of mechanical grinding and chemical action are employed and effective to achieve a desired planarization. The chemical mechanical polishing process of the invention provides an enhanced removal rate from high points on surfaces, as compared with recessed areas, thereby planarizing the substrate.

During the 1980's, IBM developed the fundamentals for the CMP process. Previously (and still used in many fabs today) plasma etching or reactive ion etching (RIE); SOG (“spin on glass”); or reflow, e.g., with boron phosphorous silicate glass (BPSG) were the only methods for achieving local planarization. Local planarization refers to planarization over a small area, typically about 50 square microns, while global planarization refers to planarization over an entire chip or wafer.

CMP advantageously provides global planarization of the wafer surface (i.e. over millimeters in area). Planarity during processing improves both dielectric and metal film coverage and increases lithography, etching and deposition process latitudes. For example, global planarization ensures proper depth of focus for lithographic processing and better thin metal film deposition and step coverage resulting in increased wafer yield and lowers cost. CMP has also been adapted for the planarization of inter-layer dielectrics (WLD) and for multilayered metal structures. CMP is becoming important, if not essential, for multi-layer metal and damascene processes.

As is known in the art, a damascene polishing technique can be used to form plugs. This process involves forming an opening (or via) in the dielectric layer, over-filling the opening with a conductive material, typically a metal, and then removing the excess material by polishing leaving an inlaid conductive path through the dielectric. A dual damascene technique, as is also known in the art, can be employed to simultaneously form metallic plugs and lines. Dual damascene involves forming an opening comprising a lower contact or via opening section in communication with an upper channel section, over-filling the opening and channel section with a conductive material to simultaneously form an electrically connected conductive plug and line combination, and then removing the excess material.

With CMP, polishing and removal occur by a combination of chemical and mechanical polishing action. CMP utilizes a combination of solid abrasives and chemicals to achieve the combination polishing action. Thus, the CMP process may be considered to be a two part mechanism: the first step consists of chemically modifying the surface of the material to be removed and the second step consists of the removal of the altered material by mechanical grinding. These steps are not discrete, of course, but occur simultaneously during the polishing process. One challenge in CMP is to control both the chemical attack of the targeted layer and its rate of removal and yet maintain a high selectivity to the offending features without causing damage to the wafer or the complex structures built thereon. An added complexity is that the wafer is a complex sandwich of materials with widely differing mechanical, electrical and chemical characteristics, all built on an extremely thin, flexible substrate.

One type of chemical mechanical polishing, termed fixed-abrasive CMP, provides abrasive material embedded within the surface of the polishing pad. Alternatively, and more commonly, CMP processes use a slurry comprising very hard, solid abrasive particles suspended in a chemical solution. The slurry is interposed between a pad and a wafer, with both typically being caused to rotate in conjunction with the application of pressure. The wafer or substrate may be of any suitable type, such as a semiconductor device structure having the material present thereon. Under normal operating conditions, the head (holding the sample) and platen (the opposing surface onto which a polishing pad is mounted) rotate in an opposite sense to one another. The head pressure is the pressure exerted on the substrate by the polishing pad. Pressure must be applied by the polishing pad to the substrate at an appropriate level, because too high a pressure will cause fracture of most semiconductor substrates. The head pressure can be readily empirically determined for a specific CMP application, using the Preston equation, according to which the removal rate for a surface is directly proportional to both the head pressure and velocity of the polishing pad. The polish rate is zero in the absence of either pressure or velocity.

As used herein, the term “slurry” is intended to be broadly interpreted to include solutions, suspension, dispersions and semi-solids, as forms of the CMP composition of the present invention, containing abrasive particles (silica, alumina, etc.) and a component chemically reactive with the material to be removed. Polishing slurries are critical to the CMP process. The type and size of the abrasive, the solution pH, and presence of (or lack of) oxidizing chemistry are very important to the success of the CMP process.

The chemical component may comprise an oxidizing agent or other chemical that is reactive with the layer to be removed and preferably produces a reaction product that is readily removed from the substrate. In metal polishing, the exposed metal surface reacts with the slurry chemistry to form an oxide or other volatile surface layer that is easier to remove by abrasion than the metal. As the reacted surface layer is removed by abrasion, the underlying metal surface is exposed to chemical attack and the removal cycle continues. Under ideal conditions the rate of formation of the volatile surface layer will equal the rate of removal. The etch rate of the metal is highly dependent on pH and the presence of other compounds, which may include surface-activating agents, chelants, regenerators, abrasives, and the like.

When the pH is too high, the reacted layer may become impenetrable to the chemistry and the metal polish rate becomes undesirably slow. When the pH is too low, the presence of highly corrosive oxidants (e.g. ferric nitrate) cause corrosion problems with the polishing equipment. Conventionally, oxidants used in metal polishing have included nitric acid, hydrogen peroxide, cesium and ferric nitrate solutions, and ferric cyanide solutions. Because of the short chemical stability of slurries comprising these oxidants, many slurries are made up at the time of use.

Metal CMP slurries must have a high selectivity for removing the unwanted metal compared to the dielectric features on the wafers. Metal polishing selectivity to oxide generally ranges from 20 to 100:1, depending on the metal type. Typically, the etch rate of the dielectric is low for metal-polishing compositions, for example less than 100 A/min. Tungsten metal should have a polish selectivity to oxide >50:1, and copper should have >140:1 oxide selectivity. Metal etch rates for such selectivity can be up to 7000 A/min, though in many applications etch rates of 500 A/min are acceptable. The metal removal rate should be between 1700 to 3500 A/minute without excessive “dishing” of the metal plugs or erosion of the oxide substrate.

The CMP processes are very sensitive to structural pattern density which will affect metal structure “dishing” and oxide erosion. Large cross-sectional area features are planarized slower than small cross-sectional area features.

Interlayer dielectric (oxide) polishing also appears to involve two concurrent processes: a mechanical process involving plastic deformation of the surface, and chemical attack by hydroxide to form silanol bonds.

| | | |
|---|---|---|
| SiO₂ + 2H₂O | [symbol] | Si(OH)₄ (aq) pH < 9 log K₅ = −2.7 |
| SiO(OH)₄ + OH | [symbol] | SiO(OH)₃ + H₂O pH < 9 log K₅ = −1.7 |
| SiO(OH)₃ | [symbol] | polynuclear species pH > 10.5 |
| 2Si(OH)₄ | [symbol] | (HO)₃Si—O—Si(OH)₃ + H₂O |

In a slurry (colloidal suspension) the pH is important. For the silicon oxide system the pH needs to be in the 10 to 11.5 range. If the pH is too high polynuclear species may start to precipitate in an unpredictable manner. Also, at too high a pH Si—Si bonds may form through a condensation process. Oxide etch rates beneficially are in the range of 500 to 3000 A/min, for example 1700 A/mm. Other important features of the silicon surface will influence the etch rates and final surface conditions, such as the amount and extent of metal contamination and the presence of micro scratches. The typical silicon surface is terminated with —OH groups under neutral or basic conditions and is therefore hydrophilic. These —OH groups activate the surface to a number of possible chemical or physio-absorption phenomena. The Si—OH groups impart a weak acid effect which allows for the formation of salts and the exchange of the proton (H⁺) for various metals (similar to the ion exchange resins). The Si—O⁻ and Si—OH moieties can also act as ligands for complexing Al, Fe, Cu, Sn and Ca. The surface is extremely dipolar and so electrostatic charges can accumulate or be dissipated depending on the pH of the bulk solution, ion concentration and charge. This accumulated surface charge can be measured as the Zeta potential.

The Zeta potential provides an electrostatic potential measurement of the double layer of ions (cations and anions) that surround each particle in solution. The Zeta potential, which can be positive or negative, is a function of the solution pH as well as the chemical constituency of the particles. Also, it is possible to change the Zeta potential through the use of surfactants. For example, octylphenol polyethylene (9-10 ethylene oxide units) combined with hydroxylamines at a pH of 9.5 reduced the surface tension and resulting surface roughness. A well designed slurry comprises particles that neither flocculate or settle but rather maintain their suspension.

Also, if the silicon (Si) surface underneath the oxide layer is exposed because of an over aggressive polishing process, this could cause electrochemical problems because silicon has a modest redox potential which will allow Cu, Au, Pt, Pb, Hg and Ag to “plate” on the silicon surface. Exposure to light will also affect the redox reaction for Cu.

Finally, CMP processes have customarily suffered from poor nonuniformity values. Nonuniformity quantifies the removal rate over many points over a wafer. For example, pre-CMP thickness measurements are taken by measuring a plurality of points on each wafer and then, post-CMP thickness measurements are taken at the same points. If s is the standard deviation of the thickness removed for the measured points and x is the mean (average) thickness removed for the measured points, the nonuniformity (NU)(%) is equal to 100 s/x. Typically, good nonuniformity values are below five percent.

The art continues to seek new CMP techniques and compositions for carrying out CMP processes. There is especially a need for providing CMP techniques and compositions that are particularly adapted for removal of copper and copper-containing films such as are employed in the fabrication of conductive structures for semiconductor devices. It therefore is an objective of the present invention to provide improved CMP techniques and compositions. It is another object of the invention to provide one or more CMP slurry compositions that demonstrate good selectivity between the conductive layer and barrier layer while providing good nonuniformity values.

The present invention ameliorates or overcomes one or more of the shortcomings of the prior art by providing one or more CMP slurry compositions that have one or more of the following characteristics: 1) an improved metal/barrier selectivity, 2) minimal dishing and erosion, and 3) good nonuniformity. The present invention is directed to a chemical mechanical planarization or polishing slurry that is able to selectively polish the conductive and dielectric portion of a semiconductor layer.

### SUMMARY OF THE INVENTION

One embodiment of this invention is a method for chemical mechanical polishing of tungsten comprising: providing a semiconductor substrate comprising on one face tungsten and a second material, typically a dielectric material; providing a chemical mechanical polishing composition containing between about 2% and about 15% ammonium persulfate, between about 0.1% and about 10% of a secondary oxidizer, a pH adjusting compound to adjust the pH of the composition, and optionally an abrasive, wherein the pH of the composition is between about 6.5 to about 12; and movably contacting the substrate face with a pad exerting between about 0.1 and about 9 psi pressure on the substrate and with the composition under conditions that tungsten is removed at a rate different than the removal of the second material. The secondary oxidizer comprises potassium peroxymonosulfate, peroxymonosulfuiric acid, imidazole, malonic acid, or malonamide. The second material is a dielectric material. The chemical mechanical polishing composition may include at least one of potassium iodate, potassium periodate, or lithium periodate. The chemical mechanical polishing composition may include periodic acid, peracetic acid, oxalic acid, citric acid, lactic acid, NH₄HF₂, or a mixture thereof. The chemical mechanical polishing composition may include hydrogen peroxide, a perborate, a peroxhydrate, or a urea hydrogen peroxide complex. The chemical mechanical polishing composition may include an organic acid selected from the group consisting of gluconic, malonic acid, lactic acid, succinic acid, tartaric acid, citric acid, oxalic acid, or salts thereof. The process may further include a second polishing operation comprising the steps of: providing a second chemical mechanical polishing composition comprising an oxidizer, a pH adjusting compound to adjust the pH of the composition, and optionally an abrasive, wherein the pH of the composition is between about 3 to about 12; movably contacting the substrate face with a pad exerting between about 0.1 and about 9 psi pressure on the substrate and with the second composition under conditions that tungsten is removed at a rate different than the removal of the second material. The second chemical mechanical polishing composition may include the same components as the first composition, but the relative amounts and/or the pH may differ.

Another embodiment of this invention is method for chemical mechanical polishing of tungsten comprising: providing a semiconductor substrate comprising on one face tungsten and a second material, typically a dielectric material; providing a chemical mechanical polishing composition comprising between about 0.5% and about 10% periodic acid, between about 0.1% and about 10% of a secondary oxidizer, a pH adjusting compound to adjust the pH of the composition, and optionally an abrasive, wherein the pH of the composition is between about 4 to about 12; and movably contacting the substrate face with a pad exerting between about 0.1 and about 9 psi pressure on the substrate and with the composition under conditions that tungsten is removed at a rate different than the removal of the second material. The secondary oxidizer comprises potassium peroxymonosulfate, imidazole, malonic acid, or malonamide, and wherein the second material is a dielectric material. The chemical mechanical polishing composition may include at least one of potassium iodate, potassium periodate, or lithium periodate. The chemical mechanical composition may include ammonium persulfate, peracetic acid, oxalic acid, NH₄HF₂, or a mixture thereof. The secondary oxidizer may include hydrogen peroxide, a perborate, a peroxhydrate, or a urea hydrogen peroxide complex. The chemical mechanical polishing composition may additionally comprise an organic acid selected from the group consisting of gluconic, malonic acid, lactic acid, succinic acid, tartaric acid, citric acid, oxalic acid, or salts thereof. In one embodiment the process further comprising a second polishing operation comprising the steps of: providing a second chemical mechanical polishing composition comprising an oxidizer, a pH adjusting compound to adjust the pH of the composition, and optionally an abrasive, wherein the pH of the composition is between about 3 to about 12; and movably contacting the substrate face with a pad exerting between about 0.1 and about 9 psi pressure on the substrate and with the second composition under conditions that tungsten is removed at a rate different than the removal of the second material. The second chemical mechanical polishing composition may include the same components as the first composition, but the relative amounts and/or the pH may differ.

Another embodiment of the invention is a method for chemical mechanical polishing of copper comprising: providing a semiconductor substrate comprising on one face copper and a second material, typically a dielectric material; providing a chemical mechanical polishing composition comprising between about 1% and about 20% hydroxylamine, hydroxylamine sulfate, hydroxylamine nitrate, or mixture thereof, between about 0.1% and about 10% of a carboxylic acid, a pH adjusting compound to adjust the pH of the composition, and optionally an abrasive, wherein the pH of the composition is between about 3 to about 12; movably contacting the substrate face with a pad exerting between about 0.1 and about 9 psi pressure on the substrate and with the composition under conditions that copper is removed at a rate different than the removal of the second material. The chemical mechanical polishing composition may include potassium peroxymonosulfate, imidazole, malonic acid, or malonamide, and wherein the second material is a dielectric material. The chemical mechanical polishing composition may include at least one of potassium iodate, potassium periodate, lithium periodate, periodic acid, peracetic acid, oxalic acid, NH₄HF₂, or a mixture thereof. The secondary oxidizer may be an aggressive oxidizer such as hydrogen peroxide, a perborate, a peroxhydrate, or a urea hydrogen peroxide complex. The chemical mechanical polishing composition may additionally include an organic acid selected from the group consisting of gluconic, malonic acid, lactic acid, succinic acid, tartaric acid, citric acid, oxalic acid, or salts thereof. The process of the invention further includes a second polishing operation comprising the steps of: providing a second chemical mechanical polishing composition comprising an oxidizer, a pH adjusting compound to adjust the pH of the composition, and optionally an abrasive, wherein the pH of the composition is between about 3 to about 12; and movably contacting the substrate face with a pad exerting between about 0.1 and about 9 psi pressure on the substrate and with the second composition under conditions that copper is removed at a rate different than the removal of the second material. The second chemical mechanical polishing composition may include the same components as the first composition, but the relative amounts and/or the pH may differ.

In yet another embodiment the invention contemplates a method for chemical mechanical polishing of aluminum comprising: providing a semiconductor substrate comprising on one face aluminum and a second material, typically a dielectric material; providing a chemical mechanical polishing composition comprising between about 2% and about 12% ammonium persulfate, a pH adjusting compound to adjust the pH of the composition, and optionally an abrasive, wherein the pH of the composition is between about 2 to about 8; and movably contacting the substrate face with a pad exerting between about 0.1 and about 9 psi pressure on the substrate and with the composition under conditions that aluminum is removed at a rate different than the removal of the second material. The chemical mechanical polishing composition may advantageously include potassium peroxymonosulfate, peroxymonosulfuric acid, imidazole, malonic acid, or malonamide. The second material is typically a dielectric material. The chemical mechanical polishing composition may include at least one of potassium iodate, potassium periodate, lithium periodate, periodic acid, peracetic acid, oxalic acid, citric acid, lactic acid, or a mixture thereof. The chemical mechanical polishing composition may include hydrogen peroxide, NH₄HF₂, a perborate, a peroxhydrate, or a urea hydrogen peroxide complex. In one embodiment the chemical mechanical polishing composition additionally includes an organic acid selected from the group consisting of gluconic, malonic acid, lactic acid, succinic acid, tartaric acid, citric acid, oxalic acid, or salts thereof. The invention further contemplates a second polishing operation comprising the steps of: providing a second chemical mechanical polishing composition comprising an oxidizer, a pH adjusting compound to adjust the pH of the composition, and optionally an abrasive, wherein the pH of the composition is between about 3 to about 12; and movably contacting the substrate face with a pad exerting between about 0.1 and about 9 psi pressure on the substrate and with the second composition under conditions that alumina is removed at a rate different than the removal of the second material. The second chemical mechanical polishing composition may include the same components as the first composition, but the relative amounts and/or the pH may differ.

In another embodiment the invention includes a method for chemical mechanical polishing of a substrate comprising: providing a semiconductor substrate comprising on one face a metal and a second material, typically a dielectric material; providing a chemical mechanical polishing composition comprising between about 0.1% and about 10% of ammonium hydroxide, NH₄HF₂, peracetic acid, or mixture thereof, a pH adjusting compound to adjust the pH of the composition, and optionally an abrasive, wherein the pH of the composition is between about 2 to about 13; and movably contacting the substrate face with a pad exerting between about 0.1 and about 9 psi pressure on the substrate and with the composition under conditions that metal is removed at a rate different than the removal of the second material. The chemical mechanical polishing composition may include potassium peroxymonosulfate, peroxymonosulfuric acid, imidazole, malonic acid, or malonamide, and wherein the second material is a dielectric material. The chemical mechanical polishing composition may include at least one of potassium iodate, potassium periodate, lithium periodate, periodic acid, peracetic acid, oxalic acid, citric acid, lactic acid, or a mixture thereof. The process of claim 33 wherein the chemical mechanical polishing composition comprises hydrogen peroxide, a perborate, a peroxhydrate, or a urea hydrogen peroxide complex. The chemical mechanical polishing composition may additionally include an organic acid selected from the group consisting of gluconic, malonic acid, lactic acid, succinic acid, tartaric acid, citric acid, oxalic acid, or salts thereof. The invention further contemplates a second polishing operation comprising the steps of: providing a second chemical mechanical polishing composition comprising an oxidizer, a pH adjusting compound to adjust the pH of the composition, and optionally an abrasive, wherein the pH of the composition is between about 3 to about 12; movably contacting the substrate face with a pad exerting between about 0.1 and about 9 psi pressure on the substrate and with the second composition under conditions that the metal is removed at a rate different than the removal of the second material.

Another embodiment of the invention is a method for chemical mechanical polishing of copper comprising: providing a semiconductor substrate comprising on one face copper and a second material, typically a dielectric material; providing a chemical mechanical polishing composition comprising between about 0.1% and about 10% ammonium persulfate, at least one of a secondary oxidizer, an organic acid, or a chelating agent, a pH adjusting compound to adjust the pH of the composition, and optionally an abrasive, wherein the pH of the composition is between about 3 to about 8; and movably contacting the substrate face with a pad exerting between about 0.1 and about 9 psi pressure on the tungsten substrate and with the composition under conditions that tungsten is removed at a rate different than the removal of the second material. The secondary oxidizer may include potassium peroxymonosulfate, imidazole, malonic acid, potassium iodate, potassium periodate, lithium periodate, or malonamide, periodic acid, oxalic acid, or mixtures thereof. The second material is a dielectric material. The chemical mechanical polishing composition advantageously comprises an organic acid selected from the group consisting of gluconic, malonic acid, lactic acid, succinic acid, tartaric acid, citric acid, or salts thereof.

In yet another embodiment is a method for chemical mechanical polishing of tungsten comprising: providing a semiconductor substrate comprising on one face tungsten and a second material, typically a dielectric material; providing a chemical mechanical polishing composition comprising between about 2% and about 20% hydroxylamine, between about 0.1% and about 10% of a secondary oxidizer, a pH adjusting compound to adjust the pH of the composition, and optionally an abrasive, wherein the pH of the composition is between about 7 to about 12; and movably contacting the substrate face with a pad exerting between about 0.1 and about 9 psi pressure on the substrate and with the composition under conditions that tungsten is removed at a rate different than the removal of the second material. The secondary oxidizer comprises potassium peroxymonosulfate, peroxymonosulfuric acid, imidazole, malonic acid, or malonamide. The chemical mechanical polishing composition may include at least one of potassium iodate, periodic acid, peracetic acid, potassium periodate, NH₄HF₂, or lithium periodate. In one embodiment the secondary oxidizer is hydrogen peroxide, a perborate, a peroxhydrate, or a urea hydrogen peroxide complex. The chemical mechanical polishing composition may additionally include an organic acid selected from the group consisting of gluconic, malonic acid, lactic acid, succinic acid, tartaric acid, citric acid, oxalic acid, citric acid, or salts thereof.

In yet another embodiment, the invention contemplates a method for chemical mechanical polishing of tungsten comprising: providing a semiconductor substrate comprising on one face tungsten and a second material; providing a chemical mechanical polishing composition comprising between about 1% and about 15% Fe(NO₃)₃ , between about 0.1% and about 10% of a secondary oxidizer, a pH adjusting compound to adjust the pH of the composition, and optionally an abrasive, wherein the pH of the composition is between about 0.5 to about 2; and movably contacting the substrate face with a pad exerting between about 0.1 and about 9 psi pressure on the substrate and with the composition under conditions that tungsten is removed at a rate different than the removal of the second material.

### DESCRIPTION OF PREFERRED EMBODIMENTS

The present invention ameliorates one or more of the shortcomings of the prior art by providing one or more CMP slurry compositions that have one or more of the following characteristics: 1) an improved metal/barrier selectivity, 2) minimal dishing and erosion, and 3) good nonuniformity.

Substrates

The substrates include all substrates normally used for integrated circuit manufacture, including but not limited to Al, Cu, W, Tantalum, as well as other metals, metallic compounds, and alloys. Because no two metal or alloy systems will have the same regions of chemical activity, Pourbaix diagrams can be used to examine the effect of pH on removal rates (as well as relative removal rates, vis-á-vis selectivity) of one or more target material on a given wafer. The formulations of the invention are also useful, for example, for polishing silica, tantalum, tantalum nitride, tantalum aluminum nitride, and the like.

Some metals exhibit particularly good polishing characteristics when polished with certain formulations. For example, a preferred tungsten polishing formulation used periodic acid (PIA) at pH 7 to 9, especially in combination with citric acid and other chelators at this pH range.

The chemical mechanical planarization slurry typically comprises a reducer or an oxidizer and at least one abrasive. Unless expressly stated otherwise, all CMP formulations described herein have an aqueous base. However, the base could also be partly or entirely a polar organic solvent, provided the oxidizers, acids, chelators, and the like are soluble.

Abrasives

Conventional slurries either are acidic or basic, and generally contain alumina, silica, polycrystalline diamond, zirconium oxide, magnesium oxide, or cerium oxide (ceria) abrasive particles. Other abrasives can include any colloidal and relatively inert solid, including for example barite, diamond, silicon carbide, and even some plastics. The abrasive material may be of a single type or may comprise mixtures of different abrasive components. Further, the abrasive material of such same or different types, may have a uniform particle size and shape, or the abrasive material may be heterogeneous in such particle size and/or shape characteristics. The concentration of particles in the abrasive slurry may be widely varied in the broad practice of the present invention, depending on the specific application or results.

One preferred abrasive according to the present invention comprises colloidal silica. Colloidal silica as a slurry comprising between about 1 to 25% solids, with an average particle size range of 20-150 nanometers and particle size mean of 71-73 nanometers, is commercially available from Dupont as DP106 (TM). A more processed (milled and filtered) product is commercially available from EKC Technology, Inc. and sold thereby under the name, MicroPlanar™ CMP9000™. Colloidal silica in a concentration in between 5% and 50%, for example between about 25% to 33.5% by weight, with a particle size (range) of from about 20 to about 150 nanometers with an average particle size of from about 40 to about 100 nanometers, for example about 71-73 nanometers, is useful. Each abrasive has ideal pH ranges in which they perform best. The processed silica has a preferred pH range of about 6 to about 11, preferably from about 8.1 to about 8.5.

In preferred embodiments the slurries contain between 1% and 10% abrasives.

Another preferred abrasive composition comprises milled alumina. Milled alumina with a Particle Size range of 20-250 nanometers and a Particle Size mean of 90 nanometers is available commercially from Baikowski as CR-85 (TM). A further processed milled alumina is available from EKC Technology, Inc. and sold thereby under the name, MicroPlanar™ CMP9001™. Milled alumina is advantageously at a concentration between about 5% to about 50%, for example between about 15% to about 25% by weight, with a particle size (range) of between about 10 nanometers to about 300 namometers, preferably between about 20 to 200 nanometers with an average particle size of about 90 nanometers. The preferred pH ranges for alumina is from about 3 to about 8, more preferably about 3.5 to about 5, and even more preferred from about 4 to about 4.5.

Yet another preferred abrasive comprises diamond particles, for example polycrystalline diamond of an average particle size of between about 10 and about 100 nanometers, preferably between about 30 and about 50 nanometers.

Another preferred abrasive includes polymer particles, for example polymethacrylate or polymethacrylic particles, of between 0.1 to about 50 microns in diameter.

Abrasive particles preferably have a morphology of very rounded particles (no sharp edges) because sharp edges may produce scratches and defects. The abrasive particles should also, of course, be chemically inert such that it neither decomposes when exposed to the CMP composition nor does it catalyze decomposition of other components of the CMP composition.

The amount of abrasive in the final CMP composition can vary as is known in the art. Typically, abrasive is present in the final composition in an amount ranging from about 0.001% to about 20%, more typically between about 1% and about 5%, by weight.

The polishing surface usually is a planar pad made of a relative soft, porous material, such as polyurethane. The pad usually is mounted on a planar platen. Continuous pad devises also are used. CMP compositions devoid of an abrasive, where the pad contains the abrasive, also are being used.

Oxidizers

One or more oxidizers are essential for CMP formulations designed for use with metals.

The formulation may comprise one or more oxidizing agents, stabilizers, chelating agents, buffers, etc. which, in combination with an abrasive, provide a slurry suitable for chemical mechanical polishing. Accordingly, it is one aim of the invention to provide suitable oxidizer compositions to meet the variety of challenges in the application of chemical mechanical polishing to next-generation semiconductor processing.

A preferred oxidizer is hydroxylamine Hydroxylamine can be employed as an oxidizing agent and its pH may be adjusted from about 10 to a value in the acidic range, i.e., about 2, by adding various types of inorganic acids such as Nitric or Sulfuric acid or organic acids such as citric acid. Hydroxylamine-based formulations typically contain between about 1% and about 20%, preferably between about 2% and about 15%. When hydroxylamine is used as a secondary oxidizer in a formulation having another oxidizer, the CMP formulation contains between 0.1 and about 8%, typically between 0.3% and 5%, of hydroxylamine.

For aluminum and tungsten, pH ranges of about 6.5 to about 10 are preferred with hydroxylamine formulations.

A preferred embodiment for a variety of substrates is a formulation containing 1-5% Hydroxylamine, preferably about 2% Hydroxylamine; between 3 and 5%, preferably about 4.2% of an inorganic acid, for example phosphoric acid, nitric acid, hydrochloric acid, sulfuric acid, or mixture thereof, preferably sulfuric acid; between 1 and 5%, preferably about 3% hydroxylamine sulfate, hydroxylamine nitrate, or mixture thereof, preferably hydroxylamine sulfate; between 0.05 and 1%, preferably about 0.2% of a carboxylic acid, for example citric acid, oxalic acid, or lactic acid, preferably citric acid; and the balance water. This formulation is particularly effective with MicroPlanar CMP9060 Al₂O₃ at about a 12.3% level.

A second preferred oxidizer is periodic acid (PIA). Periodic acid-based formulations typically contain between about 1% and about 20%, preferably between about 2% and about 10%. When periodic acid is used as a secondary oxidizer in a formulation having another oxidizer, the CMP formulation contains between 0.1 and about 5%, typically between 0.3% and 2%, of periodic acid.

Another preferred oxidizer is ammonium persulfate (APS). Ammonium persulfate is, when used as the principal oxidizer, present in an amount between about 1% and about 20%, preferably between about 2% and about 10%, and more preferably between about 3% and 7% by weight. When Ammonium persulfate is used as a secondary oxidizer in a formulation having another oxidizer, the CMP formulation contains between 0.1 and about 8%, typically between 0.3% and 5%, of Ammonium persulfate. Ammonium persulfate is particularly useful when matched with an organic acid, for example gluconic acid and/or oxalic acid.

Hydroxylamine Nitrate (HAN) serves as a mild oxidizing agent having a pH of about 3 to about 3.5 and includes a Nitrate anion that provides good removal rate controllability of the tantalum and/or a tantalum nitride barrier underlying the copper. Hence, one advantage of Hydroxylamine nitrate over the known prior is that it has better removal rate controllability as compared with Hydrogen Peroxide.

A further Hydroxylamine chemistry pursuant to the present invention is in the form of hydroxylamine sulfate (HAS). Hydroxylamine sulfate comes as a salt and is a Sulfate salt of Hydroxylamine. Pursuant to the present invention, Hydroxylamine Sulfate is employed to control the rate at which the barrier is hit exposed and gone polished through. Thus, the present invention plays a balance between HAN and Hydroxylamine sulfate to obtain peak performance, i.e., to obtain the most advantageous barrier removal rate. Thus, pursuant to the present invention, Hydroxylamine sulfate is a way of introducing another oxidizing agent into the slurry while controlling the concentration or availability of the anions, whether it be Nitrate or Sulfate. Additionally, HDS and HAN can be used to modify the pH.

The hydroxylamines, ammonium persulfate, and/or periodic acid is in many applications beneficially used in conjunction with other oxidizers. Additional oxidizers, for example periodates (including periodic acid), iodates, or a mixture thereof, advantageously present in an amount up to about 20%, for example from about 1% to 10% by weight. Still other additional oxidizers include peroxomonosulfates, peroxymonosulfuric acid, perborates, and malonamide, present in a cumulative amount up to about 20%, for example between about 1% and 10% by weight.

The invention particularly relates to mixtures of more than one oxidizer, for example a composition containing Hydroxylamine, Hydroxylamine Sulfate, Citric acid, Sulfuric acid, DI water, and Benzotriazole. One example includes about 1 to about 3% hydroxylamine; about 1% to about 5% hydroxylamine sulfate; about 0.1% to about 0.5% citric acid (solid), about 2% to about 3% Sulfuric acid, about 75% to about 92% water, about 0.1% to about 3% Benzotriazole, wherein the amounts of chemicals are chosen such that the resulting pH Range is preferably 4-5, more preferably about 2.9 to about 3.1.

The ammonium persulfate can also be incorporated with one or more hydroxylamines, wherein the total concentration of Ammonium persulfate and hydroxylamines are below about 20%. Bases that can be used to adjust the oxidizing solution's pH include sodium hydroxide, potassium hydroxide, magnesium hydroxide, magnesium carbonate and imidazole, among others.

In another embodiment the oxidizer comprises hydroxylamine. Hydroxylamine can be employed as an oxidizing agent and its pH may be adjusted from about 12, preferably from about 10, to a value in the acidic range by adding various types of acids such as nitric or sulfuric acid.

Hydroxylamine and hydroxylamine derivatives (chloride, sulfate, nitrate or other salts) perform differently under different pH conditions. With respect to its redox chemistry, hydroxylamine can be viewed a hybrid between hydrazine and hydrogen peroxide. Hydroxylamine is a more selective (controllable) oxidation and reducing agent. This dual capability is achieved by shifting the pH from the acid to basic media, i.e.

| | | |
|---|---|---|
| Cu⁺² (NH₄OH) | [symbol] | Cu⁺ pH 9-11 Eᵥ = −0.08 Reduction |
| Cu⁺ (H₂SO₄) | [symbol] | Cu⁺² pH˜0-1 Eᵥ = +0.34 Oxidation |

The redox potential for hydrogen peroxide (acidic) and Hydroxylamine (in acid and base)(E_{V} at SHE) are:

| | |
|---|---|
| H₂O₂ | [symbol] O₂ + 2H⁺ + 2e⁻ Eᵥ = +0.68 |
| 2NH₂OH + 4OH⁻ | [symbol] N₂O + 5H₂O + 4e⁻ Eᵥ = −1.05 |
| 2NH₃OH⁺ | [symbol] N₂O + 6H⁺ + H₂O + 4e⁻ Eᵥ = −0.05 |

Few metal ions are reduced to the zero oxidation state, and this is important in CMP processes to avoid contamination of the wafer surface with metal particles.

Besides being a redox agent, Hydroxylamine, like ammonia, can form complex salts with many metals including Al(SO₄)₂·NH₂OH·H₂O and Cu(x)₂·NH₂OH·H₂O. Another important advantage of using hydroxylamine-type compounds is their decomposition products. Depending on the solution pH and metal ions and concentration, Hydroxylamine will decompose to water, nitrogen, ammonia and N₂O. The formation of nitrogen even takes place through a slow internal redox reaction at pH values above 8. One advantage of using Hydroxylamine-based chemistries for the removal of copper is that the oxidation potential (Eᵥ=−1.05 V) enables copper removal at higher pH values than conventional chemistries. Under acidic conditions, hydroxylamine compounds are very stable in aqueous solution. Furthermore, Hydroxylamine's advantageously aid in removing mobile ions (sodium, potassium, iron, and other transition metal ions) from the wafer surface. Mobile ions, for example, are potentially deleterious to doping profiles and contact resistance values.

The quantity of hydroxylamine in the formulation can be any amount up to about 30%, for example between about 1% and 20%, and more preferably between about 5% and 10% by weight. In one preferred embodiment, the composition contains about 7% of a combination of hydroxylamines.

The Hydroxylamine can also be incorporated with one or more of the hydroxylamine derivatives, wherein the total concentration of hydroxylamines are preferably below about 20%, and more preferably below about 10%.

A further hydroxylamine chemistry pursuant to the present invention is in the form of hydroxylamine sulfate (HAS). Hydroxylamine sulfate is used to control the rate at which the barrier is polished. Hydroxylamine sulfate is a way of introducing another oxidizing agent into the slurry while controlling the concentration or availability of the anions, whether it be nitrate or sulfate. The Hydroxylamine sulfate has limited solubility and therefore advantageously is added as a solid where it will dissolve to some extent depending on conditions and concentration. At the preferred concentrations it is in solution.

In a third embodiment the oxidizer comprises hydroxylamine nitrate (HAN). Hydroxylamine nitrate serves as a mild oxidizing agent having a pH of about 3 to about 3.5 and includes a nitrate anion that provides good removal rate controllability of selected materials, for example a tantalum and/or a tantalum nitride barrier. Hence, one advantage of hydroxylamine nitrate over the known prior art is that it has better removal rate controllability as compared with hydrogen peroxide.

For example, a preferred polisher comprises hydroxylamine in an amount between about 0.2% to about 8%, preferably between about 1% and about 3%, for example 2% of Hydroxylamine; between about 0.2% to about 10%, preferably between about 1% and about 5%, for example 3% of hydroxylamine sulfate, between about 0.1% to about 10%, for example about 4.2% of an inorganic acid, preferably sulfuric acid; between about 0.01% to about 4%, for example about 0.2% of an organic acid, preferably citric acid, and water.

Additionally, HAS and HAN can be used to modify the pH. Another preferred polisher comprises hydryoxylamine in an amount between about 0.2% to about 8%, preferably between about 2% and about 5%, for example 3.7% of Hydroxylamine; between about 0.2% to about 5%, preferably between about 0.5% and about 2%, for example 0.8% of hydroxylamine nitrate; between about 0.1% to about 7%, preferably between about 2% and about 5%, for example 3% of hydroxylamine sulfate; and water. This composition has a preferred pH of between about 4 to about 8, preferably 5 to 7, more preferably between about 6 and about 6.8.

The additional oxidizers may also include a peroxide. Hydrogen peroxide, at about 2% to about 10%, was found to be effective when combined with between about 5% and about 15% hydryoxylamine and advantageously about 2% to about 10% of a carboxylic acid, preferably citric acid. A composition containing 10% hydrogen peroxide and 10% Hydroxylamine was found to be very aggressive. A composition comprising only 2% hydroxylamine and 10% HAN, on the other hand, was did not exhibit fast polishing rates.

Generally, hydrogen peroxide is not stable enough for commercial use. The use of hydrogen peroxide is well known in the metal CMP field, though it suffers from poor long-term stability when mixed with slurry mixtures. CMP users have made adjustments to this problem by segregating the peroxide solution from the slurry until just prior to usage on the polisher; however, this segregation imposes the additional complication and cost of dual dispensing systems. A urea-peroxide combination, however, at low concentrations of between about 1% to about 10%, preferably between about 2% to about 5%, and at a pH between 4 and 5 exhibited fast but controllable etch rates.

The invention also includes combinations of oxidizers. Thus, in one embodiment the present invention uses a balance between Hydroxylamine, Hydroxylamine nitrate and Hydroxylamine sulfate to obtain peak performance, i.e., to obtain the most advantageous barrier removal rate. In another embodiment, the present invention concerns a balance between Hydroxylamine nitrate and Hydroxylamine sulfate to obtain peak performance, i.e., to obtain the most advantageous barrier removal rate.

In another embodiment the composition can also include additional oxidizers, for example periodates (including periodic acid), iodates, present in an amount up to about 20%, for example from between about 1% to 10% by weight. A formulation comprising between about 0.1% to about 2% KIO4 is an aggressive CMP formulation. KIO3 and LiIO3, alone or together, at a concentration between about 0.1% and about 5% were effective, especially at a neutral of slightly basic pH, for example between about 7 and about 8.

Other oxidizers include peroxomonosulfates, peroxymonosulfuric acid, perborates, and malonamide, present in a cumulative amount up to about 20%, for example between about 1% and 10%. Ozone, which may be produced and then solubilized into the CMP formulation or contacted with the substrate as a separate phase (i.e., bubbles, or separate but more continuous gas and liquid phases) is also an aggressive secondary oxidizer.

Another primary oxidizer is peracetic acid. Surprisingly, the aggressiveness of formulations containing peracetic acid increased with an increase in pH between pH values of about 1.5 and about 8. Sodium percarbonate was found to be effective at low concentrations, for example between 0.1% and about 8%. NaOCl was found to be marginally effective.

Additional secondary oxidizers include the oxidizers described in the examples.

Acids and Bases

It is noted that the etching ability of formulations on specific substrates is dependent on the pH of the formulation. As discussed above the pH can often be adjusted with buffering amounts of hydryoxylamine and salts thereof, and with acidic chelators, and with organic acids such as citric acid, and finally with inorganic acids. Sulfuric acid is one preferred pH-modifying compound, and it is added in an amount typically between 0.1% and 5% to adjust the formulation pH to the desired value. Other acids can be used, especially nitric acid. Substitute acids may include any of the inorganic acids, for example Acetic acid, phosphoric acid, Perchloric acid and/or Hydrochloric acid. In the case of multivalent acids, in some cases a salt thereof may be added for pH control.

The composition can additionally or alternatively have additional carboxylic acids, in an amount ranging up to 20%, for example between about 1% and 10% by weight. In another embodiment the carboxylic acids are present in an amount between about 0.01% and 10%, and preferably between about 0.1% and 1% by weight. Organic acids such as citric acid, succinic acid, tartaric acid, oxalic acid, malonic acid, and gluconic acid are preferred for selected embodiments.

These organic acids should have PKa values lower thydroxylamine nitrate the pH of the planarization solution. It is desirable to have these acids in their corresponding anion form as dictated by the composition pH. For example, peroxymonosulfuric acid (Caro's acid) (H₂SO₅) or its salts are very strong oxidizing agents, (E₀=1.44V). The acid form has one proton with a dissociation constant similar to sulfuric acid while the second proton has a PKa of only 9.4.

Citric acid works to complex copper (i.e., in a copper I or copper II state) so as to preclude copper metal from redepositing or coming out of solution because of other secondary chemical reactions. Additional acids, for example sulfuric acid and nitric acid, are preferred additives. Sulfuric acid provides a way of modifying the pH of the oxidizer so that the hydroxylamine chemistries are on the acidic side and are therefore oxidizers. Additionally or alternatively, nitric acid may be employed to provide a way of modifying the pH of the oxidizer so that the hydroxylamine chemistries are on the acidic side and are therefore oxidizers. Substitute acids may include acetic acid, perchloric acid and/or hydrochloric acid. The quantity of acids may in part depend on the desired pH. Typically, between about 0.1% to about 10% acid may be added.

In one preferred embodiment, the CMP formulation comprises between about 5% and about 15%, for example between about 8% and about 12%, preferably 10% hydryoxylamine combined with between about between about 0.1% and about 10%, preferably between about 0.5% and about 3%, of a carboxylic acid, preferably Oxalic acid, lactic acid, gluconic acid, citric acid, or a mixture thereof.

There are other additives that can be added to hydroxylamine oxidizers that can also be used in the CMP process. Bases that can be used to adjust the oxidizing solution's pH include sodium hydroxide, potassium hydroxide, magnesium hydroxide, magnesium carbonate and imidazole, among others. The composition according to the present invention may include a hydrazine inhibitor.

Citric acid works as a complexing agent for copper for helping to retain metals, i.e., copper in a complex form (i.e., in a copper I or copper II state) so as to preclude copper from redepositing or coming out of solution because of other secondary chemical reactions. Sulfuric additionally acid provides a way of modifying the pH of the oxidizer so that the hydroxylamine chemistries are on the acidic side and are therefore oxidizers. These acids must be paired with one of the principal oxidizers, i.e., hydroxylamine, HAN, Hydroxylamine sulfate, PIA, Ammonium persulfate, and the like.

Bases may include any of the bases known to the art, including alkali and earth metal hydroxides, oxides, carbonates, and the like. Magnesium oxide or hydroxide is preferred.

Chelating Agents

According to a further embodiment, it is possible to add chelating agents such as alkyl beta-diketones (i.e. 2,4 pentanedione, etc.), EDTA, DPTA, aromatic phenolic aldehydes (i.e. salicylaldehyde, etc.), bis(hydroxypropyl)hydroxylamine, anisaldehyde, alpha hydroxy isobutyric acid, aromatic dioxygenated compounds (i.e. benzoin and benzil), and catechol and catechol derivatives. Chelating agents may be added in concentrations ranging from about 2 ppm to 15 wt. %.

Gallic acid is another compound that under mildly acidic conditions may complex with certain group III-XII metals. The catechol and gallic acid family of compounds function either as corrosion inhibitors (at higher concentrations, e.g. between about 0.5 to 20 wt. %) or as metal chelators (between about ppm to 0.5 wt. %).

In one embodiment of the invention, the slurry composition of the invention includes a sufficient amount of a selectively oxidizing and reducing compound, i.e., hydroxylamine or a hydroxylamine salt to produce a differential removal of a metal and a dielectric material; a pH adjusting compound to provide a pH that makes the selectively oxidizing and reducing compound provide the differential removal of a metal and a dielectric material; and an ammonium peroxy compound, i.e., ammonium peroxydisulfate.

In another embodiment of the invention, the slurry composition of the includes a sufficient amount of a first selectively oxidizing and reducing compound, i.e., hydroxylamine or a hydroxylamine salt to produce a differential removal of a metal and a dielectric material; a pH adjusting compound to provide a pH that makes the selectively oxidizing and reducing compound provide the differential removal of a metal and a dielectric material; Optionally an acid, preferably an organic acid, optionally a second oxidizer, and optionally a chelating agent.

In addition to adjusting the slurry pH, the composition and concentration of the individual oxidizer and abrasive chemistries and their respective pH values; the solution flow rates; the platen and head rotation speeds; and the down force may be adjusted either individually or in combination in order to give the desired polishing results. For example, the oxidizer solution may be between about 1 to 40% by weight solids, and more preferably between about 5 to 20%. The solution comprising the abrasive may be between about 1 to 40% by weight solids, and more preferably between about 5 to 20%. Similarly, additional chemistries may be added to the polishing process. The concentrations of suitable supplemental chemistries may vary from between about 0.1 to 99%. The liquid flow rate for the oxidizer solution may be between about 1 to 100 ml/min., more preferably between about 5 to 50 ml/min., and most preferably about 20 ml/min. Similarly, the abrasive flow rate may be between about 1 to 100 ml/min., more preferably between about 5 to 50 ml/min., and most preferably about 20 m/min. The platen speed may be between about 10 to 100 rpm, and more preferably between about 20 to 50 rpm. Similarly, the head speed may be between about 10 to 100 rpm, and more preferably between about 20 to 50 rpm. The head pressure (down force) may be between about 0.5 to 6 psi, more preferably between about 1 to 4 psi, and most preferably between about 2 to 3 psi.

Other Components

In some cases inhibitors, for example corrosion inhibitors, may be beneficial in a CMP application. Such inhibitors may reduce, for example, dishing out caused by very agressive oxidizers. Furthermore, and pursuant to the present invention, the formulation may include benzotriazole (BTA). Benzotriazole is typically employed as a corrosion inhibitor for controlling the chemical etching of copper. The oxidizers, according to the present invention, may also include a hydrazine inhibitor. Benzotriazole is typically employed as a corrosion inhibitor for controlling the chemical etching of copper. Benzotriazole may be replaced with 2,4-pentandione dioxime and/or 1,6-dioxaspiro[4,4] nonane 2,7-dione (di-ether).

The compositions of the present invention have different efficacies with different substrates.

### EXAMPLES

### Example 1

### Copper Substrates

Currently, copper and copper alloys are receiving considerable attention as replacement materials for, inter alia, aluminum and aluminum alloys in VLSI and ULSI multilevel metallization systems. Copper has an even lower resistivity than aluminum, and significantly higher electromigration resistance. However, a primary problem with integrating copper metal into multilevel metallization systems is the difficulty of patterning the metal for devices of submicron minimum feature size after blanketing an interdielectric layer for revealing the filled channels and vias.

There are two general process approaches for polishing copper wafers. The first approach uses a single phase slurry. A copper single-step slurry process involves only one phase slurry. The CMP process is continuous, but polishing steps can be divided into many as needed. In general a high polishing pressure process step can remove copper topography and planarize the surface efficiently with good removal uniformity. After then a lower polishing pressure step is employed to remove the remaining copper and continuing to remove barrier layer (Ta/TaN or W) with a lower removal rate. The copper dishing and oxide erosion can be controlled the same as those using two-phase slurry. The ILD layer (TEOS) removal rate can be controlled <200 A/min.

The CMP process is continuous, though several discrete polishing steps can be used. An initial high pressure process step removes copper topography and planarizes the surface efficiently with good removal uniformity. A subsequent lower pressure step using the same slurry is employed to remove the remaining copper and continuing to remove barrier layer material (Ta/TaN or W) with a lower removal rate. The copper dishing and oxide erosion can be controlled the same as those using two-phase slurry. The ILD layer (TEOS) removal rate can be controlled to less than 200 A/min.

The second approach uses two (or more) slurries in separate polishing steps. In the first phase, a first slurry comprising an oxidizer and an abrasive, i.e., silica or alumina, is used to planarize the copper topography quickly and then continue to remove the copper metal while maintaining good uniformity. In the second phase, a second slurry comprising an oxidizer and a abrasive is used to remove the barrier layer (TaN or Ta) with high removal rates (>700 A/min) and low TEOS removal (<200 A/min). Overall wafer %NU should less than 5%. The selectivity of Cu to the barrier film should be ˜1:1. The use of colloidal silica in the second phase advantageously serves as a built-in buffing step possibly eliminating the need for a third polishing step dedicated to buffing the oxide. Similarly, diamond abrasive provides an excellent polish.

The first composition is more aggressive than the second composition on a two step process, or vice versa. The aggressiveness of the composition can be changed by altering the abrasives, changing the amount and/or type of oxidizers or the pH of the CPM slurry, the addition of chelators, and the like.

In one preferred form, the present invention provides a polishing slurry comprised of an oxidizer including one or more hydroxylamine chemistries and at least one abrasive that is able to selectively polish the copper portion of a copper and tantalum and/or a tantalum nitride layer. By means of an example, a 10% hydroxylamine nitrate slurry removed 3000A copper metal on a 300A Ti metal layer, where the composition had a pH-removal rate relationship as follows: pH 3 gave 100 A/min; pH 4 gave 125 A/min; and pH 5 gave 1000 A/min. The removal rate increased with increasing pH due to the oxidation potential. This is the reverse of the expected pH effect from the Pourbaix diagram. Normally, so long as an oxidizer is supplied to the dissolved film such that there is more of a chemical effect rather than a polishing effect, copper at a very low pH values is easily dissolved. In contrast, and surprisingly, hydroxylamine-based chemistries do not seem to have this same relationship. The removal rate is low for low pH values and as the pH increases (still on the acidic side) the removal rate goes up. This is counter-intuitive because closer to a pH of 5 or 6, the copper oxides (copper I and copper II) get harder and thus presumably more protective. Applicants, however, have found that the hydroxylamine chemistries become more aggressive with increased pH values.

For comparison, when the free base hydroxylamine (5% in DI water) was tested with the same type of copper wafer, the etch rate was just 75 A/min. A 10% ammonium hydroxide solution had an etch rate of 100 A/min. It is known that ammonium hydroxide solutions will dissolve copper slowly, but if oxidizing agents (air or oxygen) are introduced then the etch rate can be increased. With copper, the preferred pH range can be between about 2 and 6, depending on the desired planarization rate. Solutions comprising Hydroxylamine at various pH values, which are typically in the pH range of about 2-10, preferably between about 3-9, could be used for controlled etching of copper.

In one embodiment, one preferred formulation was prepared with 2% hydryoxylamine, 4.2% Sulfuric acid, 3% HAS, 0.2% Citric acid, and 90.76% water admixed with 12.3% by weight MicroPlanar CMP9060™ A12O3. It is noted that citric acid provides pH control, can be a very modest oxidizer, and can act as a chelating agent. For this reason citric acid may be present in larger concentrations, for example between about 5% and about 20%. One formulation, containing 15% citric acid and 9% hydroxylamine, with a pH of 4.1, gave a polishing rate of 742 Angstroms per minute when added at 50 ml per minute with 3% MOTCO abrasive, using a Politex pad revolving at 33 rpm on a 3″ IWS substrate with 2 psi pressure. This compares to about 75 Angstroms per minute without citric acid.

Another preferred CMP formulation “A” comprises 3.5% hydroxylamine, 2.4% hydroxylamine nitrate, and distilled (DI) water, with a pH of about 6.7. A mixture of formulation A with 10% colloidal silica gave copper polishing rates of 7200 Angstroms per minute, with a NU % of 6.2%. The same formulation with TaN gave an polishing rates of 650 Angstroms per minute with an NU % of 14.7%. The process involves applying 5 psi down force pressure, 0 psi back pressure, 60 rpm table speed (22.5 inch diameter) and 61 rpm carrier speed (8 inch diameter). The slurry composition, when employed according to the above process, provides a Cu:TaN selectivity of approximately 11.1 and a copper nonuniformity (NU %) of approximately 6.2%. The hydroxylamine solution of formulation A is preferably between about 0.5 to 5 wt. %, more preferably between about 1 to 4%, and most preferably about 3.5%. The hydroxylamine nitrate solution of oxidizer A is preferably between about 0.5 to 5%, more preferably between about 1 to 3%, and most preferably about 3%.

A third embodiment B contained comprises 3.5% hydroxylamine, 0.8% hydroxylamine nitrate, 3% hydroxylamine sulfate, and distilled (DI) water, with a pH of about 6.7. This slurry, with 10% silica, gave a copper etch rate of 7100 Angstroms per minute and an NU % of 5%. This same slurry gave a TaN etch rate of 515 Angstroms/minute with a NU % of 16%. The conditions were similar to those described above, that is, the process involves applying 5 psi down force pressure, 0 psi back pressure, 60 rpm table speed (22.5 inch diameter) and 61 rpm carrier speed (8 inch diameter). The hydroxylamine solution of oxidizer B is preferably between about 0.5 to 5 wt. %, more preferably between about 1 to 4%, and most preferably about 3.5%. The hydroxylamine nitrate solution of oxidizer B is preferably between about 0.5 to 5%, more preferably between about 0.5 to 2%, and most preferably about 1%. The hydroxylamine sulfate (solid) of oxidizer B is preferably between about 0.5 to 5%, more preferably between about 1 to 3%, and most preferably about 3%.

Another oxidizer formulation C tested comprises 2% hydroxylamine, 3% hydroxylamine sulfate, 0.2 citric acid, 2.7%-2.8% sulfuric acid, DI water, and 2.5% benzotriazole at a pH of about 3. In another embodiment the amount of abrasive can be increased to greater thydroxylamine nitrate 25%, for example about 40%. A composition of formula C with 40% alumina gave a copper polishing rate of 6900 (all polishing rates are in Angstromes/minute) with an NU % of 8.2%. The process involves applying 5 psi down force pressure, 0 psi back pressure, 90 rpm table speed (22.5 inch diameter) and 90 rpm carrier speed (8 inch diameter). When the table speed and carrier speed are reduced to 75 rpm, and the downward force is reduced to 3 psi, the copper polishing rate is 3120 with an NU % of 14.6%, and the TaN polishing rate is 240 with an NU % of 16.7%.

This oxidizing formulation is even effective when diluted with water, for example, 2 parts of formulation C, 1 part water, and 1 part alumina abrasive gave a copper polishing rate of 6540 and an NU % of only 5.5%. The process involves applying 5 psi down force pressure, 0 psi back pressure, 90 rpm table speed (22.5 inch diameter) and 90 rpm carrier speed (8 inch diameter). When the table speed is reduced to 70 rpm, and the downward force is reduced to 2 psi, the copper polishing rate is 2240 with an NU % of 8.6%, and the TaN polishing rate is 171 with an NU % of 14.3%.

When hydroxylamine and hydroxylamine salts are used together in a formulation, the ratio of Hydroxylamine to Hydroxylamine sulfate, Hydroxylamine nitrate, or both Hydroxylamine sulfate and Hydroxylamine nitrate is advantageously between about 5:1 to 1:10, preferably between about 2:1 to 1:4. For example, a composition may contain 5% Hydroxylamine and 1% each of Hydroxylamine sulfate and Hydroxylamine nitrate.

Another tested oxidizer composition, formulation D, comprised of 2% hydroxylamine, 3% hydroxylamine sulfate, and DI water. The hydroxylamine solution of oxidizer D is preferably between about 0.5 to 5 wt. %, more preferably between about 1 to 4%, and most preferably about 2%. The hydroxylamine sulfate (solid) of oxidizer D is preferably between about 0.5 to 5%. Another preferred oxidizer (Oxidizer “E”) according to the present invention comprises hydroxylamine, hydroxylamine sulfate, sulfuric acid, and DI water. One example of approximate component concentrations for Oxidizer E is shown in the following table.

Oxidizer E

| | Concentration |
|---|---|
| Component | (wt. %) |
| Hydroxylamine (50% solution) | 4.0% |
| Hydroxylamine Sulfate (solid) | 3.0% |
| Sulfuric acid H₂SO₄ (95-98% acid) | 2.7% |
| DI water | 90.3% |

Oxidizer E composition has a preferred pH range of about 3 to 3.2. The hydroxylamine solution of oxidizer E is preferably between about 1 to 10 wt. %, more preferably between about 2 to 8%, and most preferably about 4%. The hydroxylamine sulfate (solid) of oxidizer E is preferably between about 0.5 to 5%, more preferably between about 1 to 3%, and most preferably about 3%. The sulfuric acid of oxidizer E is preferably between about 1 to 5 wt. %, more preferably between about 2 to 3%, and most preferably about 2.7%.

Oxidizer Components (Oxidizer “F”)

Another preferred oxidizer (Oxidizer “F”) according to the present invention comprises hydroxylamine, hydroxylamine sulfate, sulfuric acid, and DI water. One example of approximate component concentrations for Oxidizer F is shown in the following table.

Oxidizer F

Oxidizer F Composition has a preferred pH range of about 3 to 3.2.

| | Concentration |
|---|---|
| Component | (wt. %) |
| Hydroxylamine (50% solution) | 4.0% |
| Hydroxylamine Sulfate (solid) | 3.0% |
| Sulfuric acid H₂SO₄ (95-98% acid) | 2.7% |
| Citric acid (solid) | 0.2% |
| DI water | 90.1% |

The hydroxylamine solution of oxidizer F is preferably between about 1 to 10 wt. %, more preferably between about 2 to 8%, and most preferably about 4%. The hydroxylamine sulfate (solid) of oxidizer F is preferably between about 0.5 to 5%, more preferably between about 1 to 3%, and most preferably about 3%. The sulfuric acid of oxidizer F is preferably between about 1 to 5 wt. %, more preferably between about 2 to 3%, and most preferably about 2.7%. The citric acid of oxidizer F is preferably between about 0.05 to 1 wt. %, more preferably between about 0.1 to 0.5%, and most preferably about 0.2%.

Oxidizer Components (Oxidizer “G”)

As mentioned above, the oxidizers in accordance with the present invention may further include a hydrazine inhibitor. Another preferred oxidizer (Oxidizer “G”) according to the present invention comprises hydroxylamine sulfate, hydroxylamine, sulfuric acid, hydrazine (NH₂NH₂), 4-hydrazine benzoic acid (solid), and DI water. One example of approximate component concentrations for Oxidizer G is shown in the following table.

Oxidizer G

Oxidizer G composition has a preferred pH range of about 3.

| | Concentration |
|---|---|
| Component | (wt. %) |
| Hydroxylamine (50% solution) | 4.8% |
| Hydroxylamine sulfate (solid) | 3.0% |
| Sulfuric acid H₂SO₄ (95-98% acid) | 4.2% |
| Hydrazine (99%) | 0.2% |
| 4-hydrazine benzoic acid (solid) (HBA) | 0.03% |
| DI Water | 88.77 |

The hydroxylamine solution of oxidizer G is preferably between about 1 to 10 wt. %, more preferably between about 2 to 8%, and most preferably about 4.8%. The hydroxylamine sulfate (solid) of oxidizer G is preferably between about 0.5 to 5%, more preferably between about 1 to 3%, and most preferably about 3%. The sulfuric acid of oxidizer G is preferably between about 1 to 10 wt. %, more preferably between about 2 to 8%, and most preferably about 4.2%. The hydrazine of oxidizer G is preferably between about 0.05 to 1 wt. %, more preferably between about 0.1 to 0.5%, and most preferably about 0.2%.

Composition concentrations and the CMP process may be altered to acquire different CMP results. Typically, the CMP process includes covering the surface of the wafer with the slurry and polishing the wafer. Thus, the CMP process is effected by polish time in seconds (“s”), polish pressure (or polish down force (PSI)) (“pp”), polish table speed, RPM (“ts”), spindle speed (carrier speed), RPM (“ss”) and slurry flow in m/min (“sf”). The CMP results of the process include the mean copper removal rate (MRR) in A/min. and the within wafer nonuniformity (%) (WIWNU).

The result displayed below under the column heading “Dia-58 pt” represents 58-points diameter measurement across the whole wafer by DCE Resmap four point probe. The result under the column “Polar-49pt/6 mmEE” represents 49 points polar measurement with 6 mm edge exclusion by Resmap.

### EXAMPLE 2

### Copper Substrate with Inhibited Formulations

The use of an inhibitor, a fluoridizer, or both may be advantageous in CMP formulations. In further accordance to the present invention and as delineated above, BTA is used to block the surface of copper from corroding or dissolving away in the absence of an oxidizer, or corroding or dissolving away at a controlled rate in the presence of an oxidizer.

As an alternative to BTA, 2,4 pentandione dioxime is used to block or control the rate at which the surface of copper corrodes or dissolves away. The compound 2,4 pentandione dioxime is given by the chemical formula:

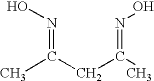

A characteristic of BTA is that it tends to form a resilient mono layer in the form of a cover salt, i.e., an insoluble copper reaction product at the copper surface. This layer can be removed only by polishing under extreme chemical conditions that include the use of strong acids or bases. Furthermore, BTA can stack crystallize on top of the mono layer so as to physically scratch the wafer under normal CMP processes as a result of the sharp edges of the BTA crystals. Hence, copper is not easily polished with BTA present.

2,4-pentandione dioxime also forms a copper reaction product with copper but apparently stops at the monolayer, yet provides blocking that was discovered to be approximately equivalent with BTA. That is, 2,4-pentandione dioxime and BTA both form insoluble products at approximately the same rate and at apparently about the same degree of insolubility. However, 2,4-pentandione dioxime can form insoluble products at pH levels as low as 2 and 3. Thus, 2,4-pentandione dioxime complexes copper without stack crystallizing further pentandione dioxime layers on the initial monolayer of 2,4-pentandione dioxime.

In one embodiment, the present invention is comprised of an oxidizer (Oxidizer “D” from Example 1), 2,4-pentandione dioxime (an Insoluble Complexing Agent), H₂O₄, an alumina abrasive and DI Water mixed to form the Slurry 5 Composition.

Composition concentrations for one example are shown in the following table. It should be noted that the concentration of, inter alia, the Insoluble Complexing Agent of the present invention may be changed to alter the resultant slurry.

Slurry 5 Composition

The slurry composition has a preferred pH range of about 2.82.

| Component | Concentration (wt. %) |
|---|---|
| Oxidizer D | 60.0% |
| 2,4-Pentandione dioxime | 0.05% |
| H₂SO₄ | 1.9% |
| Abrasive B | 20.0% |
| DI Water | 18.05% |

The CMP process variables and results for two examples using the Slurry 5 Composition are shown in the following table.

| | | Dia-58 pt | | Polar-49 pt/6 mmEE | |
|---|---|---|---|---|---|
| | CMP Process | Mean Removal | | Mean Removal | |
| Slurry | s/pp/ts/ss/sf | Rate (Å/min) | WWNU % | Rate (Å/min) | WWNU (%) |
| Slurry 5 | 60/5/90/90/175 | 7777 | 6.2% | 7870 | 4.8% |
| Slurry 5 | 60/3/75/75/175 | 3910 | 12.3% | 4325 | 10.4% |

The first above process using the Slurry 5 Composition is achieved with a polish time of 60 seconds, a polish pressure of 5 psi, a polish table speed of 90 RPM, a spindle speed of 90 RPM and a slurry flow of 175 ml/min.

The second process example using the Slurry 5 Composition is achieved by using a polish time of 60 seconds, a polish pressure of 3 psi, a polish table speed of 75 RPM, a spindle speed of 75 RPM and a slurry flow of 175 ml/min. Note that the Slurry 5 Composition is extremely advantageous in that it provides a large WIWNU (or synonymously, NU %) window of 4.8% to 10.4% to account for process variations.

Copper Slurry Composition (Slurry “6” Composition)

In another preferred form, the present invention doubles the weight percent of 2,4-pentandione dioxime in the Slurry 5 Composition to form a Slurry 6 Composition.

Composition concentrations for one example of the Slurry 6 Composition are shown in the following table and is should be noted that the concentration of, inter alia, the Insoluble Complexing Agent (2,4-pentandione dioxime) of the present invention may be changed to alter the resultant slurry.

Slurry 6 Composition

The slurry composition has a preferred pH range of about 2.78.

| Component | Concentration (wt. %) |
|---|---|
| Oxidizer D | 60.0% |
| 2,4-pentandione dioxime | 0.1% |
| H₂SO₄ | 1.9% |
| Abrasive B | 20.0% |
| DI Water | 18% |

The CMP process and results for a first example employing the Slurry 6 Composition are shown in the following table. This process may be altered using the same slurry to acquire different CMP results.

CMP Process and Results Utilizing the Slurry 6 Composition

| | | Dia-58 pt | | Polar-49 pt/6 mmEE | |
|---|---|---|---|---|---|
| | CMP Process | Mean Removal | | Mean Removal | |
| Slurry | s/pp/ts/ss/sf | Rate (Å/min) | WWNU % | Rate (Å/min) | WWNU (%) |
| Slurry 6 | 60/5/90/90/175 | 7878 | 5.2% | 8185 | 4.7% |
| Slurry 6 | 60/3/75/75/175 | 4434 | 7.2% | 4874 | 9.8% |

Thus, the first above process uses the Slurry 6 Composition and is achieved using a polish time of 60 seconds, a polish pressure of 5 psi, a polish table speed of 90 RPM, a spindle speed of 90 RPM and a slurry flow of 175 ml/min.

The second process example using the Slurry 6 Composition is achieved using a polish time of 60 seconds, a polish pressure of 3 psi, a polish table speed of 75 RPM, a spindle speed of 75 RPM and a slurry flow of 175 ml/min.

Copper Slurry Composition (Slurry “7” Composition)

In another preferred form, the present invention is comprised of the Oxidizer D, 1,6-dioxaspiro(4,4) nonane 2,7-dione (diether) (an Insoluble Complexing Agent), H₂O₄, an abrasive and DI water mixed to form the Slurry 7 Composition.

As noted above, preferred Oxidizer D composition, according to the present invention, comprises 4% hydroxylamine, 3% hydroxyl ammonium salt and 93% DI water.

Composition concentrations, for one example, are shown in the following table and is should be noted that the concentration of, inter alia, the Insoluble Complexing Agent of the present invention may be changed to alter the resultant slurry.

Slurry 7 Composition

The slurry composition has a preferred pH range of about 2.78.

| Component | Concentration (wt. %) |
|---|---|
| Oxidizer D | 60.0% |
| 1,6-Dioxaspiro[4,4] nonane | 0.05% |
| 2,7-dione (Diether) | |
| H₂SO₄ | 1.9% |
| Abrasive | 20.0 |
| DI Water | 18.05% |

CMP process variable and results for two examples using Slurry 7 are shown in the following table.

CMP Process and Results Utilizing Slurry 7

| | | Dia - 58 pt | | Polar - 49 pt/6 mm EE | |
|---|---|---|---|---|---|
| | | Mean | | Mean | |
| | CMP Process | Removal | WWNU | Removal | WWNU |
| Slurry | s/pp/ts/ss/sf | Rate (Å/min) | (%) | Rate (Å/min) | (%) |
| Slurry 7 | 60/5/90/90/17 | 6192 | 6.5% | 6171 | 4.1% |
| | 5 | | | | |
| Slurry 7 | 60/3/75/75/17 | 2822 | 4.5% | 2891 | 5.4% |
| | 5 | | | | |

The first process using the Slurry 7 Composition is achieved using a polish time of 60 seconds, a polish pressure of 5 psi, a polish table speed of 90 RPM, a spindle speed of 90 RPM and a slurry flow of 175 ml/min.

The second process example using the Slurry 7 Composition is achieved using a polish time of 60 seconds, a polish pressure of 3 psi, a polish table speed of 75 RPM, a spindle speed of 75 RPM and a slurry flow of 175 ml/min.

Copper Slurry Composition (Slurry “8” Composition)

In another preferred form, the present invention doubles the weight percent of 1,6-dioxaspiro(4,4) nonane 2,7-dione (diether) (an Insoluble Complexing Agent).

Composition concentrations for one example of the Slurry 8 Composition are shown in the following table and is should be noted that the concentration of, inter alia, the Insoluble Complexing Agent of the present invention may be changed to alter the resultant slurry.

Slurry 8 Composition

The slurry composition has a preferred pH range of about 2.72.

| Component | Composition (wt. %) |
|---|---|
| Oxidizer D | 60.0% |
| 1,6-dioxaspiro(4,4)nonane 2,7-dione | 0.10% |
| (diether) | |
| H₂SO₄ | 2.0% |
| Abrasive | 20.0 |
| DI Water | 18% |

The CMP process and results for two examples employing the Slurry 8 Composition are shown in the following table. This process may be altered using the same slurry to acquire different CMP Results. Abrasive A is colloidal silica, and abrasive B is alumina.

CMP Process and Results Utilizing the Slurry 8 Composition

| | | Dia-58 pt | | Polar-49 pt/6 mmEE | |
|---|---|---|---|---|---|
| | CMP Process | Mean Removal | | Mean Removal | |
| Slurry | s/pp/ts/ss/sf | Rate (Å/min) | WWNU % | Rate (Å/min) | WWNU (%) |
| Slurry 8 | 60/5/90/90/175 | 4654 | 6.2% | 4545 | 5.2% |
| Slurry 8 | 60/3/75/75/175 | 2308 | 5.2% | 2331 | 8.8% |

Thus, the first above process using the Slurry 8 Composition is achieved by using a polish time of 60 seconds, a polish pressure of 5 psi, a polish table speed of 90 RPM, a spindle speed of 90 RPM and a slurry flow of 175 ml/min.

The second process example using the Slurry 8 Composition is achieved using a polish time of 60 seconds, a polish pressure of 3 psi, a polish table speed of 75 RPM, a spindle speed of 75 RPM and a slurry flow of 175 ml/min.

As mentioned above, the oxidizers in accordance with the present invention may further include sulfuric and/or citric acid. Sulfuric acid provides a way of modifying the pH of the oxidizer so that the hydroxylamine chemistries are on the acidic side and are therefore oxidizers. Citric acid works as a complexing agent for copper for helping to retain copper in a complex form (i.e., in a copper I or copper II state) so as to preclude copper from redepositing or coming out of solution because of other secondary chemical reactions. Below are some polishing rates obtained with various Oxidizer E formulations, where Oxidizer E contains 2% Hydroxylamine, 3% HAS, 2.7% sulfuric acid, balance water.

CMP Mixing Ratios, Processes and Results for
Slurry Compositions Comprising Oxidizer E

| | Cu RR | | TaN RR |
|---|---|---|---|
| | CMP | CMP | CMP |
| | Process | Process | Process |
| | s/pp/ts/ss/sf | s/pp/ts/ss/sf | s/pp/ts/ss/sf |
| Slurry Composition | 5/2/90/90/** | 3/2/75/75/** | 3/2/75/75/** |
| 1) 60% Oxidizer E, 20% | 7867 | 4785 | 195 |
| Abrasive B, 20% DI water | | | |
| 2) 60% Oxidizer E, 20% | 4648 | 2557 | 182 |
| Abrasive B, 0.5% | | | |
| NH₂NH₂ and 19.5% DI water | | | |
| (pH ˜ 3) | | | |
| 3) 60% Oxidizer E, 20% of | 6001 | 3444 | 193 |
| Abrasive B, 0.25% NH₂NH₂, | | | |
| and 19.75% DI water | | | |
| (pH ˜ 3) | | | |
| 4) 30% Oxidizer 9011, 20% | 586 | 183 | 185 |
| Abrasive B, 0.5% | | | |
| H₂O₂ 5% MPX073, | | | |
| and 44.5% DI water | | | |
| 5) 4.8% Hydroxylamine (50% | 7028 | 3833 | 179 |
| solution), 3.0% | | | |
| Hydroxylamine Sulfate | | | |
| (solid), 5.0% | | | |
| NH₂NH₂, 4.2% H₂SO₄, | | | |
| 20% Abrasive B, and | | | |
| 63.0% DI water | | | |

In further preferred forms, the present invention includes slurry compositions comprised of Oxidizer E. The following table delineates static etching rate (A/min.) at 130° F. for twenty-two specific examples and static etching rate at a few different temperatures for a few of the twenty-two specific examples of slurry compositions in accordance with the present invention and further delineates composition concentrations (mixing ratios) for the twenty-two examples.

Static Etching Rate For Copper CMP Slurry Compositions

The stock solution for the 9011 Oxidizer is 1% Hydroxylamine nitrate, 0.016% BTA, and 0.006% nitric acid. It is then diluted down at the percentage values in the Tables.

The stock solution for MPX-073, also sometimes called CMP9060, is 0.2% BTA in water.

| | Static Etch Rate | | |
|---|---|---|---|
| | Room | | |
| Slurry Composition | Tempera- | 130° | 150° |
| (balance DI water) | ture | F. | F. |
| 1) 60% Oxidizer E, 10% Abrasive B | 50.6 | 1391 | 1440 |
| 2) 60% Oxidizer E, 20% Abrasive B | 84.5 | 1305 | 1398 |
| 3) 60% Oxidizer E, 0.1% DARVEN C, | 191.4 | 727 | N/A |
| 20% Abrasive B | | | |
| 4) 60% Oxidizer E, 20% Abrasive B, | 7 | −179 | N/A |
| 1.0% NH₂NH₂ (pH ˜ 3) | | | |
| 5) 60% Oxidizer E, 20% Abrasive B, 0.5% | 45 | 49 | N/A |
| NH₂NH₂ (pH ˜ 3) | | | |
| 6) 60% Oxidizer E, 20% Abrasive B, 0.4% | N/A | 921 | N/A |
| NH₂NH₂ (pH ˜ 5) | | | |
| 7) 60% Oxidizer E, 20% Abrasive B, 0.3% | N/A | 1819 | N/A |
| NH₂NH₂ (pH ˜ 4) | | | |
| 8) 60% Oxidizer E, 20% Abrasive B, 0.25% | N/A | 1579 | N/A |
| NH₂NH₂ (pH ˜ 3) | | | |
| 9) 60% Oxidizer E, 20% Abrasive B, 0.1% | N/A | 1955 | N/A |
| NH₂NH₂ (pH ˜ 3) | | | |
| 10) 60% Oxidizer E, 20% Abrasive B, 0.25% | N/A | 796 | N/A |
| NH₂NH₂, 2.5% Hydroxylamine (pH ˜ 3) | | | |
| 11) 60% Oxidizer E, 20% Abrasive B, 0.35% | N/A | 463 | N/A |
| NH₂NH₂, 2.5% Hydroxylamine (pH ˜ 3) | | | |
| 12) 60% Oxidizer E, 20% Abrasive B, 0.35% | N/A | 2394 | N/A |
| NH₂NH₂, 5% MPX-073, | | | |
| 2.5% Hydroxylamine (pH ˜ 3) | | | |
| 13) 60% Oxidizer E, 20% Abrasive B, 0.5% | N/A | 279 | N/A |
| NH₂NH₂, 2.5% Hydroxylamine (pH ˜ 3) | | | |
| 14) 20% of Abrasive B, 3% H₂O₂ | N/A | 523 | N/A |
| 15) 20% of Abrasive B, 3% H₂O₂, 0.5% | N/A | 787.5 | N/A |
| NH₂NH₂ (pH ˜ 3 (HNO₃ adjustment)) | | | |
| 16) 30% Oxidizer 9011*, 0.6% H₂O₂, | 55.5 | 2995 | N/A |
| 20% Abrasive B *9011 Oxidizer = 90.764% | | | |
| DI water, 1.23% Hydroxylamine nitrate | | | |
| (at 82%), 8% CMP9060, and 0.006% | | | |
| nitric acid (pH ˜ 2.3-2.7) | | | |
| 17) 30% Oxidizer 9011, 0.6% H₂O_{2,} | 0 | 293 | 1350 |
| 20% Abrasive B, 5% MPX-073 | | | |
| 18) 30% Oxidizer 9011, 0.6% H₂O₂, | 243 | 408 | 750 |
| 20% Abrasive B | | | |
| 19) 0.6% H₂O₂, 20% Abrasive B | N/A | 1137 | N/A |
| 20) 30% Oxidizer 9011, 0.6% H₂O₂, | 0 | 200 | N/A |
| 20% Abrasive B, 5% MPX-073. | | | |
| 21) 60% Oxidizer E, 30% Abrasive B | 85.4 | 1261 | N/A |
| 22) 60% Oxidizer E, 40% Abrasive B | 103.5 | 716 | N/A |

Copper CMP Slurry Compositions Comprising Oxidizer F

In further preferred forms, the present invention includes slurry compositions comprised of Oxidizer F. The following table delineates fourteen specific examples of slurry compositions in accordance with the present invention and further delineates composition concentrations (mixing ratios), some comparison etch rate data between using a DI water for the balance of the slurry verses using abrasive B. The stock solution for oxidizer 9007 is 4% Hydroxylamine (50% solution), 3% HAS, 4.2% sulfuric acid, and 0.2% citric acid. In contrast, Oxidizer F contained only 2.7% sulfuric acid. It is then diluted down at the % values in the Tables.

Static Etching Rate For Copper CMP Slurry Compositions

| | Etch Rate (A/min) | |
|---|---|---|
| Slurry Composition | DI | Abrasive B |
| (balance DI water) | Balance | Balance |
| 1) 60% Oxidizer F | 63 | 365 |
| 2) 60% Oxidizer F (pH ˜ 2) | 12 | 203.6 |
| 3) 60% Oxidizer F, 3% NH₄NO₃ | −87 | 153 |
| 4) 60% Oxidizer F, 0.1% DARVEN C | −11 | 191.4 |
| 5) 60% Oxidizer F, 1% NH₄NO₃ (pH ˜ 3) | 7 | N/A |
| 6) 60% Oxidizer F, 1% TMAH (pH ˜ 3) | 580 | N/A |
| 7) 60% Oxidizer F, 1% Choline Hydroxide | 789 | N/A |
| (pH ˜ 3) | | |
| 8) 30% Oxidizer 9011, 0.3% H₂O₂ | 73.5 | 21 |
| containing 20% DP106 silica | | |
| 9) 30% Oxidizer 9011, 0.6% H₂O₂, | N/A | 55.5 |
| 20% Abrasive B | | |
| 10) 30% Oxidizer 9011, 0.6% H₂O₂, | N/A | 5.5 |
| 20% Abrasive B, 5% MPX-073 | | |
| 11) 20% Abrasive B, 60%, Oxidizer 9011, 0.3% | N/A | 238 |
| H₂O₂ | | |
| 12) 20% Abrasive B, 30% Oxidizer 9007, 0.3% | N/A | 50.5 |
| H₂O₂ | | |
| 13) 50% Oxidizer 9011, 0.5% H₂O₂ | 575 | N/A |
| 14) 50% Oxidizer 9011, 0.3% H₂O₂ | 415 | N/A |

Copper CMP Slurry Composition (Slurry “9” Composition)

In another preferred form, the present invention is comprised of Oxidizer G and Abrasive B mixed to form a Slurry 9 Composition. In one example, and according to the present invention, the mixing ratio, process, removal rate data, and the static etch rate for the Slurry 9 Composition is shown in the following table.

Slurry 9 Composition: Mixing Ratio, Process and Removal Rate (RR)

| | | | | | Static |
|---|---|---|---|---|---|
| | | | | | Etching |
| | Process | | Process | | Rate @ |
| Slurry 9 Composition | 5/0/90/90 | | 5/0/75/75 | | 130° F. |
| (balance DI water) | Cu RR | NU % | Cu RR | Tan RR | RR |
| 3.0% Hydroxylamine | 9112 | 3.2% | 4235 | 200 | 178 |
| sulfate, 4.8% | | | | | |
| Hydroxylamine | | | | | |
| (50% solution), 4.2% | | | | | |
| H₂SO₄ (95-98% acid), | | | | | |
| 0.2% NH₂NH₂ | | | | | |
| (99%), 0.03% HBA, | | | | | |
| 20% Abrasive B | | | | | |

The first above process delineated with respect to the Slurry 9 Composition is achieved by applying 5 psi down force pressure, 0 psi back pressure, 90 rpm table speed (22.5 inch diameter) and 90 rpm carrier speed (8 inch diameter). The slurry 9 composition, when employed according to the above first process, provides a copper removal rate of 9112 A/min. and a copper nonuniformity (NU %) of approximately 3.2%.

The second above process delineated with respect to the Slurry 9 Composition is achieved by applying 3 psi down force pressure, 0 psi back pressure, 75 rpm table speed (22.5 inch diameter) and 75 rpm carrier speed (8 inch diameter). The slurry 9 composition, when employed according to the above second process, provides a Cu:TaN selectivity of approximately 21.2. That static copper etch rate for the Slurry 9 Composition is 178 A/min.

A test with 10% Hydroxylamine at pH 11.7 showed a controlled polishing rate of 75 Angstroms per minute on a 3″ IWS substrate. High pH polishing with hydroxylamine formulations may therefore provide an excellent finishing step.

Finally, a test was performed by admixing RS×110 formulation with 5, 10, and 20% Hydroxylamine. The flow rate of the slurry varied from 20 to 90 ml per minute, the pH varied from 6.6 at the 5% to 7 at the 20% formulations, and the testing was controlled using 2 psi pressure using a Politex pad at 33 rpm on 3″ IWS substrates. The polishing rate varied directly with the quantity of hydroxylamine, with 64 andgstroms per minute at 5% hydroxylamine, 954 Angstroms per minute with 10% hydroxylamine, and 1100 Angstroms per minute with 20% hydroxylamine. This data suggests that, with the RS×110 formulation, hydroxyamine concentrations in excess of 10% did not provide proportionate increases in the polishing rate.

### Example 3

### Copper Substrate With Other Oxidizers

Ammonium Persulfate

Solutions of ammonium persulfate and optionally other compounds were prepared and then tested in slurries. The pHs were adjusted prior to use. The pH range may be adjusted by any suitable means, such as by addition of acids, bases, buffers, or other components, alone or in combination, to achieve the desired results.

Ammonium persulfate (Ammonium persulfate) slurries were tested on copper substrates. A 5% Ammonium persulfate slurry at pH 3.3 was found to polish 2500 Angstroms per minute from the copper substrate on a 3″ IWS wafer. This 5% Ammonium persulfate test was repeated under more controlled conditions, at a slurry rate of 20 ml/minute, where the pH of the slurry was 3.2, where the abrasive flow was 20 ml/min, at a force of 2 psi with a spin rate of 33 rpm using a Politex pad, the polishing rate was 2000 Angstroms per minute on the 3″ IWS substrate.

Surprisingly, a 1% Ammonium persulfate slurry (ph 4.1) was found to give similar results, , showing about 2000 Angstroms per minute polishing rate even with the force reduced to 0.8 psi. This data was confirmed by a second test where 1% Ammonium persulfate, pH 5.9, at a 50 ml flow rate, with 2.5% MOYCO (TM) abrasive, gave a polishing rate of 2010 Angstroms per minute copper on a 3″ IWSW substrate with the spin rate at 33 rpm and the downward pressure 2 psi. Further reducing the Ammonium persulfate concentration, however, reduced the polishing rate. A 0.1% Ammonium persulfate slurry (pH 5.9), with the same test parameters as the above 1% test, showed a polishing rate of only 175 Angstroms per minute.

Ammonium persulfate formulations containing between 0.1% and about 5% are therefore preferred for copper substrates. The formulations may also contain chelators, other oxidizers, acids, and the like as described previously.

Periodic Acid

The oxidizer H₅IO₆ was tested at 2.5% (pH 2.5) at a flow rate of 50 ml, 2 psi pressure with a politex pad on the 3″ IWS substrate spinning at 33 rpm, gave a polishing rate of 400 Angstroms copper per minute.

Periodic acid is therefore a good oxidizer for copper substrates, particularly in the range of 0.5% to about 5%. The formulations may also contain chelators, other oxidizers, acids, and the like as described previously.

Hydroxylamine Nitrate

Hydroxylamine nitrate is often used as a secondary oxidizer. In static tests, the polishing rates of 10% Hydroxylamine nitrate formulations on copper changed radically with pH. At pH 31., the polishing rate is 120 Angstroms per minute. At pH 4, it is 150 Angstroms per minute, and at pH 5 it increases to 600 Angstroms per minute. In tests where the 10% Hydroxylamine nitrate formulation at was added at 20 ml per minute using a Politex pad at 33 rpm on a 3″ IWS substrate gave a polishing rate of 415 Angstroms per minute.

Similar conditions with a 10% Hydroxylamine nitrate formulation that included 10% periodic acid, at pH 9, gave a polishing rate of only 276 Angstroms per minute.

Examples of hydroxylamine and hydroxylamine nitrate formulations where the concentration of the two are of the same order of magnitude have been previously presented. However, including a small amount, that is, between about 0.005% and 1%, for example between 0.01% and 0.1% hydroxylamine in a composition containing 2% to 10% hydroxylamine nitrate has been shown to be beneficial. A 5% Hydroxylamine nitrate formulation with 0.01% Hydroxylamine (pH 4.2), added at 50 ml per minute when applied to a 3″ IWS substrate at 2 psi pressure at 33 rpm, gave a polishing rate of 18 Angstroms per minute. Adding an additional 0.01% Hydroxylamine to this formulation and adjusting the pH to 6, with the same test conditions, gave a polishing rate of 218 Angstroms per minute.

The Hydroxylamine nitrate/Hydroxylamine formulations are stable. A formulation with 4% Hydroxylamine nitrate and 0.01% Hydroxylamine (PH 5) was tested with 4% BAIL 10 L (TM) abrasive using an IC 1000 (TM) pad. The polishing rate on the 3″ IWS substrate was 577 Angstroms per minute. This same formulation was tested after 13 days, and the pH was 4.9, polishing rate was 703 Angstroms per minute. This same formulation was tested after 71 days, and the pH was 4.7, polishing rate was 786 Angstroms per minute.

The effect of pH on polishing rate is strong. A 2.45 Hydroxylamine nitrate with 0.01% Hydroxylamine formulation, with 2% BAIL 10 L abrasive,

### Example 4

### Tungsten Substrate With Ammonium Persulfate

Solutions of ammonium persulfate and optionally other compounds were prepared and then tested in slurries. The pHs were adjusted with NaOH or by other additives, such as by addition of acids, bases, buffers, or other components, alone or in combination, to achieve the desired results just prior to use. For tungsten substrates, the pH may be adjusted to a range of between about 1 to 12, and preferably between about 3 to 9, more preferably between 7 and 8.

The CMP experiments shown below were performed with 10,000 A tungsten wafers at 33 rpm and 2 psi. The pad was a Rodell RC 1000 on a Logitech P5M polisher. Base line polishing experiments with only an alumina slurry have determined that there is an 8× to 10× polishing factor between the Logitech and the IPEC/Westech industrial size CMP polisher.

CMP with Ammonium persulfate Slurries

| | pH | Removal Rate (A/min.) |
|---|---|---|
| 10% solution | 3 | 112 |
| 10% solution | 6 | 105 |
| 10% solution | 7.7 | 196 |
| 10% solution | 7.9 | 198 |
| 5% solution | 9 | 176 |

A test was performed with 10% Ammonium persulfate at 20 ml per minute, using Politex pads at 2 psi pressure at 33 rpm. With a 3″ IWS substrate, and a pH of 2.4, the polishing rate was only 7 Angstroms per minute. At pH 2.1 on a 3″ EMF substrate, the rate is only 18 Angstroms per minute. The polishing rate is very dependent on pH. On 3″ IWS substrates, halving the quantity of Ammonium persulfate to 5% but increasing the pH to 3.2 increased the polishing rate to 26, and at pH 4.5 the polishing rate is 50 Angstroms per minute.

Adding abrasive increases the polishing rate. Formulations containing 10% Ammonium persulfate added at 20 ml per minute with 5% LOGITECH (TM) abrasive added at 20 ml per minute, using the same Politex pad and 20 ml flowrate, has a polishing rate of 140 Angstroms per minute from a 3″ #MF substrate with a pH 2.1 formulation.

Increasing the oxidizer flowrate increased the polishing rate a modest amount. Formulations containing 10% Ammonium persulfate added at 90 ml per minute with 5% LOGITECH (TM) abrasive added at 20 ml per minute, using the IC1000 pads, has a polishing rate of 105 Angstroms per minute with a pH 6 formulation. A pH of 7.7 gave a polishing rate of 196 Angstroms per minute. A pH of 7.9 gave a polishing rate of 198 Angstroms per minute. A pH of 9, however, only gave a polishing rate of 176 Angstroms per minute.

It was found that low concentrations of Ammonium persulfate and abrasive gave low polishing rates, even at high oxidizer rates. For example, a 1% Ammonium persulfate formulation (pH 5.6) added at 100 ml per minute with 2.5% MOYCO (TM) abrasive added at 100 ml per minute gave polishing rates of 27 to 35 Angstroms per minute on a 3″ IWS substrate with an IC 1000 (TM) pad, table speed 33 rpm and pressure 2 psi. A 5% Ammonium persulfate formulation (pH 5.3) with 2.5% MOYCO (TM) abrasive gave polishing rates of 66 to 78 Angstroms per minute. A 20% Ammonium persulfate formulation (pH 3.5) with 2.5% MOYCO (TM) abrasive gave polishing rates of 117 to 136 Angstroms per minute. Surprisingly, a 10% Ammonium persulfate formulation (pH 3.5) with only 1% MOYCO (TM) abrasive gave polishing rates of 136 to 149 Angstroms per minute, suggesting that the formulation only needs a modest amount of abrasive, for example 2.5% or less. This was confirmed by a test with 3% MOYCO abrasive in 10% Ammonium persulfate formulation (pH 4.8) which gave an etch rate of 124-150 Angstroms per minute. A 5% loading of MOYCO abrasive in 10% Ammonium persulfate (pH 5.4), at the same conditions as each of the above, that is, 100 ml flow rate, 33 rpm table speed with 2 psi downward force on a 3″ IWS substrate with an IC1000 pad, gave etch rates of 125-13 Angstroms per minute.

A series of tests were performed with a 10% Ammonium persulfate formulation containing 1% MOYCO abrasive, where each test had an oxidizer flowrate of 100 ml per minute, and with 2 psi pressure of a IC1000 pad on a 3″ IWS substrate rotated at 33 rpm. At pH 3.9, the polishing rate was 133 Angstroms per minute. At pH 6 and 7, the polishing rate was 112 and 129 Angstroms per minute, showing essentially no improvement. At pH 8, however, the polishing rate was 360 Angstroms per minute. A pH of about 8 is therefore considered most aggressive for a 10% Ammonium persulfate formulation.

The polishing rate of Ammonium persulfate on tungsten is highly pH dependent. Numerous compounds can be used to modify the pH.

A 10% Ammonium persulfate formulation adjusted to pH 8.1 with magnesium hydroxide, added at 20 ml per minute with 5% LOGITECH abrasive at 20 ml per minute, using an IC1000 pad at 2 psi and 33 rpm on a 3″ IWS substrate gave polishing rates of 260 Angstroms per minute.

A series of tests were performed with a 10% Ammonium persulfate formulation adjusted with magnesium hydroxide, added at 20 ml per minute with 5% LOGITECH abrasive at 20 ml per minute, using a POLITEX pad at 2 psi and 33 rpm on a 3″ IWS substrate. The polishing rates, in Angstroms per minute, were 139 at pH 6.8, 197 at pH 7.5, and 182-212 at pH 7.7.

The addition of the oxidizer formulation to the slurry formulation results in dilution and other factors. For example, when the 10% Ammonium persulfate/magnesium hydroxide formulation at pH 8 is added to 20 ml per minute of LOGITECH abrasive, the polishing rate was not the 250 Angstroms per minute expected but was rather the lower 122 Angstroms per minute. While the data showed considerable variation, lower concentrations of oxidizer relative to the abrasive reduced the polishing rates.

Ammonium Persulfate with Malonic Acid

Another composition that was tested was composed of Ammonium persulfate with varying concentrations of malonic acid. The pH was adjusted with sodium hydroxide. The results are shown below.

TABLE
CMP with Ammonium persulfate/Malonic acid Slurries on Tungsten

| Ammonium | | | |
|---|---|---|---|
| persulfate | Malonic acid | pH | Etch Rate (A/min) |
| 10% | 1% | 6 | 162 |
| 10% | 1% | 8.1 | 460 |
| 10% | 0.4% | 8 | 291 |
| 5% | 1% | 8.8 | 265 |
| 10% | 0% | 8 | 162 |

A maximum etch rate is observed near pH 8. The malonic acid has a positive effect on the etch rate. The concentration of malonic acid is beneficially between about 0.1% and 5%, for example between 1% and 2%. The pH may be adjusted over any suitable range, such as between about 4 to 10, and more preferably between about 7 to 8.5.

Ammonium Persulfate with Gluconic Acid

Gluconic acid was much less effective. A 10% Ammonium persulfate and 2% gluconic acid formulation at a flowrate of 90 ml per minute containing 5% LOGITECH abrasive added at 20 ml per minute, with 2 psi pressure of a IC1000 pad on a 3″ IWS substrate rotated at 33 rpm, gave a polishing rate of 136 Angstroms per minute at pH 7.9.

Ammonium Persulfate with Oxalic Acid

Oxalic acid is a very effective diacid and chelating agent.

Oxalic acid in a 10% Ammonium persulfate and 1% oxalic acid formulation at a pH of 1.3 and a flowrate of 20 ml per minute, with 5% LOGITECH abrasive added at 20 ml per minute, with 2 psi pressure of a IC1000 pad on a 3″ IWS substrate rotated at 33 rpm, gave a polishing rate of 174 Angstroms per minute. An identical test with no abrasive but with a POLITEX pad gave a polishing rate of 94 Angstroms per minute. The pH has a significant effect. A 5% Ammonium persulfate and 1% oxalic acid formulation, with the pH 7.4 with no abrasive but with a POLITEX pad gave a polishing rate of 94 Angstroms per minute.

A 10% Ammonium persulfate and 1% oxalic acid formulation, adjusted to pH 8.5 with magnesium hydroxide, when added at 20 ml per minute to 5% LOGITECH abrasive added at 15 ml per minute, using a POLITEX pad at 33 rpm and 2 psi pressure, gave the very high polishing rate of 307 Angstroms per minute.

A series of tests were performed using 10% Ammonium persulfate and 1% oxalic acid formulations adjusted with magnesium hydroxide, and admixed with a 2.5% -3% MOYCO MC abrasive, with IC 1000 pads. The low pH tests showed low polishing rates, while the pH 7.5 formulation had a polishing rate of 208 Angstroms per minute.

Of course, the polishing rate for any formulation can be increased with the pressure applied. A 10% Ammonium persulfate and 1% oxalic acid formulationadded at 50 ml per minute adjusted to pH 1.2 with magnesium hydroxide, and admixed with 50 ml per minute of 2.5% MOYCO MC abrasive, with IC 1000 pads, but with a rotation of 50 rpm and a pressure of 6 psi against 8″ MOYCO substrates, gave a polishing rate of 200 Angstroms per minute. Increasing the amount of Ammonium persulfate to 20% but keeping all other concentrations and parameters the same gave a polishing rate of 300 Angstroms per minute. A 20% formulation with 1% oxalic acid and adjusted to pH 7 increased the polishing rate to 800 Angstroms per minute.

At 10% Ammonium persulfate and at a high pH, for example greater than about 8, the presence of oxalic acid is minimized. A 10% Ammonium persulfate and 1% oxalic acid formulation adjusted to pH 8.6 added at a rate of 90 ml per minute to a 5% LOGITECH abrasive slurry added at 20 ml per minute, with IC 1000 pads at 33 rpm and 2 psi against 3″ IWS substrates, gave between 302 and 321 Angstroms per minute polishing rates. Keeping all parameters, including pH, the same but removing the oxalic acid resulted in a polishing rate of 364 Angstroms per minute.

Ammonium Persulfate with Lactic Acid

Lactic acid in a 5% Ammonium persulfate and 1% lactic acid formulation at a pH of 2.3 and a flowrate of 20 ml per minute, with no abrasive but with a POLITEX pad with 2 psi pressure on a 3″ IWS substrate rotated at 33 rpm, gave a polishing rate of 2 Angstroms per a minute. In a 10% Ammonium persulfate and 2% lactic acid formulation at a pH of 3 and a flowrate of 90 ml per minute, with 5% LOGITECH abrasive added at 20 ml per minute, with 2 psi pressure of a IC1000 pad on a 3″ IWS substrate rotated at 33 rpm, gave a polishing rate of 112 Angstroms per minute. Increasing the pH to 8 resulted in a polishing rate of 282 Angstroms per minute.

Ammonium Persulfate with Potassium Peroxymonosulfate

A commercial product Caroate™ (potassium peroxymonosulfate compound), including the potassium salt of Caro's acid; empirical formula 2KHSO₆KHSO₄K₂SO₄), is a good oxidizer in aqueous system at low pH, but combined with Ammonium persulfate, it shows surprisingly good results for tungsten CMP at higher pH values. Caroate™ is a registered product of Degussa Corporation. The following removal rates are for the Logitech PM5 polisher (33 rpm, 12 inch IC1000 pad, 2 psi) on 3 inch wafers (10,000 A sputtered W), with 5% alumina slurry (50 parts of 10% alumina+90% water slurry), chemistry flow rate of 100 ml/min, and slurry flow rate of 20 ml/min. The results are shown below.

| Ammonium | | | |
|---|---|---|---|
| persulfate | | | |
| (wt. %) | Caroate ™ (wt. %) | pH | Removal Rate (A/min) |
| 10 | 1.0 | 5.5 | 90 |
| 10 | 1.0 | 7.5 | 139 |
| 10 | 1.0 | 8.7 | 349 |

Synergism between Ammonium persulfate and Caroate™ enhances removal rates, with removal rates increasing with increasing pH over the range 5.5 to 8.7. Increasing the Caroate™ concentration to 5% at pH 7 gave a polishing rate of 85 Angstroms per minute, which is no significant improvement over what would be expected from 1% Caroate™ in 10% Ammonium persulfate formulations. Additionally, Caroate™ without any Ammonium persulfate, at pH 1.8, showed only a 60 Angstroms per minute polishing rate.

Ammonium Persulfate with Malonamide

Ammonium persulfate combined with malonamide (H₂NCOCH₂CONH₂) shows W removal rates comparable with those of Ammonium persulfate+malonic acid using the Logitech PM5 polisher (33 rpm, 12 inch IC 1000 pad, 2 psi) on 3 inch wafers (10,000 A sputtered W), with 5% alumina slurry (50 parts of 10% alumina +90% water slurry), chemistry flow rate of 90 ml/min, and slurry flow rate of 20 ml/min, as shown below.

CMP with Ammonium persulfate - Malonamide Slurries

| Ammonium | | | |
|---|---|---|---|
| persulfate (wt. %) | Malonamide (wt. %) | pH | Removal Rate (A/mm) |
| 10 | 0 | 8.0 | 162 |
| 10 | 2.0 | 7.9 | 210 |
| 10 | 1.0 | 9.0 | 429 |
| 10 | 2.5 | 8.9 | 385 |
| 10 | 2.0 | 7.9 | 250 |
| 10 | 0 | 7.9 | 198 |

Malonamide enhances the W removal rate when combined with Ammonium persulfate in an aqueous system over the W removal rate of Ammonium persulfate alone. Removal rates increase with pH, and is particularly fast between pH 7.9 and pH 9.

As with previous examples, the slurry pH may be adjusted to any suitable value in order to give the desired polishing performance. For example, the slurry pH may be adjusted to a value of between about 1 to 10, and more preferably to between about 6 to 9.

Experiments with blanket W metal (10,000 A) wafer showed that a 10 wt % ammonium persulfate solution with a 5% alumina slurry removed 162 A/mm of the metal (pH 8), yet a 10 wt % ammonium persulfate mixed with a 2% KIO₄ with only a 5 wt % alumina slurry at a pH of 6.9 removed 637 A/mm. When a 2 wt % potassium iodate (KIO₃) was substituted into the ammonium persulfate solution, the polishing rate decreased to 246 A/mm. Polishing was done with a Logitech 5M polisher with a Politex felt cloth at 33 rpm and 2 psi pressure on the 3 inch wafer.

The concentration of the ammonium persulfate solution is preferably between about 2 to 20% by weight, more preferably between about 5 to 15%, and most preferably about 10 wt %. This relationship seems to hold for cases where additional oxidizers are added also. The alumina slurry is preferably between about 2 to 20% solids, more preferably between about 2 to 10%, and most preferably about 5%.

Ammonium Persulfate with Periodic Acid

In another aspect of the invention, a similar chemistry to that of the previous aspect uses a synergism between ammonium persulfate (Ammonium persulfate) and periodic acid (rather than potassium periodate) for polishing tungsten. There is a synergistic effect that enhances W removal rate when Ammonium persulfate and periodic acid are used together. The tungsten process appears to operate via the tungstate (WO4⁻) anion.

Periodic acid in water added to Ammonium persulfate increases the removal rate of W over Ammonium persulfate alone at a pH of 1; increasing the amount of periodic acid used with 10 parts Ammonium persulfate also increases the W removal rate using the Logitech PM5 polisher (33 rpm, 12 inch IC1000 pad, 2 psi), 3 inch wafers (10,000 A sputtered W), 0-3 parts NH₄OH to adjust pH, 1% alumina (10 parts of 10% alumina+90% water slurry), and chemistry/slurry addition rate of 100 ml/min, as shown below.

CMP with Ammonium persulfate/Periodic acid Slurries

| Ammonium | | | |
|---|---|---|---|
| persulfate (wt. %) | Periodic Acid (wt. %) | pH | Removal Rate (A/mm) |
| 0 | 2.0 | 1.5 | 130 |
| 10 | 2.0 | 1.1 | 386 |
| 10 | 0.5 | 3.5 | 118 |
| 10 | 2.0 | 5.2 | 388 |
| 10 | 0 | 6 | 112 |

Periodic acid clearly improves the polishing rate of Ammonium persulfate formulations when used on a tungsten substrate. The Ammonium persulfate concentration is preferably between about 2 to 20%, more preferably between about 5 to 15%, and most preferably about 10%. The concentration of the periodic acid solution is preferably between about 0 to 10% by weight, more preferably between about 0.2 to 5%, and most preferably about 2 wt %.

The periodic acid can also be the primary oxidizer. However, a 10% periodic acid and 2% Ammonium persulfate formulation at the high pH of 8.2, added at 20 ml per minute with 5% LOGITECH abrasive added at 20%, using an POLITEX pad at 2 psi and 33 rpm on a 3″ IWS substrate the disappointing polishing rate of 56 Angstroms per minute. A similar test with 10% Ammonium persulfate and 3% periodic acid at pH 1.3 gave the surprisingly high etch rate of 174 Angstroms per minute.

Ammonium Persulfate with Lithium Periodate

Ammonium persulfate can also be admixed with lithium periodate. Lithium periodate in water added to Ammonium persulfate increases the removal rate of W over Ammonium persulfate alone. In tests using the Logitech PM5 polisher (33 rpm, 12 inch IC1000 pad, 2 psi), 3 inch wafers (10,000 A sputtered W), 5% MOYCO alumina (10 parts of 10% alumina+90% water slurry), and chemistry/slurry addition rate of 100 ml/min, the lithium periodate provided modest increases in the etching rate as shown below.

CMP with Ammonium persulfate/Lithium Periodate Slurries

| Ammonium | | | Removal Rate |
|---|---|---|---|
| persulfate (wt. %) | Lithium Periodate (wt. %) | pH | (A/mm) |
| 0 | 0.4 | 7.4 | 38 |
| 8 | 0.3 | 6.4 | 112 |
| 10 | 0.3 | 2.7 | 202 |
| 10 | 0.4 | 5 | 196 |
| 10 | 0.4 | 5.5 | 298 |
| 10 | 0.4 | 8.5 | 473 |
| 10 | 0.1 | 7 | 177 |
| 10 | 0.3 | 7.5 | 237 |
| 10 | 0.3 | 7.7 | 301 |
| 10 | 0 | 6 | 112 |
| 15 | 0.1 | 6.6 | 116 |
| 15 | 0.2 | 7 | 173 |
| 15 | 0.4 | 7.3 | 321 |

One problem with lithium periodate/Ammonium persulfate formulations is that they change over time. A formulation initially containing 10% Ammonium persulfate and 0.4% lithium periodate, with 1% MOYCO, was prepared. The formulation initially had a pH of 7.6. In tests using the Logitech PM5 polisher (33 rpm, 12 inch IC1000 pad, 2 psi), 3 inch wafers (10,000 A sputtered W), 5% MOYCO alumina (10 parts of 10% alumina+90% water slurry), and chemistry/slurry addition rate of 100 ml/min, the lithium periodate had a polishing rate of 299 Angstroms per minute. After 7 days, the pH was 7.2 but the polishing rate surprisingly increased to 382 Angstroms per minute. At 14 days, however, the pH was 6.8 and the polishing rate dropped to 164 Angstroms per minute. Similar behavior was found with a 10% Ammonium persulfate, 0.4% lithium periodate, 5% alumina formulation, where the pH and polishing rates were; 7.6 and 299 Angstroms per minute at day 1; 7.2 and 244 Angstroms per minute at day 7; 6.4 and 218 Angstroms per minute at day 15; and 5.3 and 51 Angstroms per minute at day 23. Adding ABP to these formulations did not stabilize the system. While the pH generally changed only a tenth of a unit over 2 weeks, the polishing rates showed the same pattern of increasing and then decreasing.

Tests with 2.7% Ammonium persulfate and 0.08% lithium periodate (pH 7.2) with a 2.5% MOYCO alumina content showed 0-24 Angstroms per minute polishing rate, still with tests using the Logitech PM5 polisher (33 rpm, 12 inch IC1000 pad, 2 psi), 3 inch wafers (10,000 A sputtered W), and chemistry/slurry addition rate of 50 to 150 ml/min. The rate of chemical addition had little effect on the polishing rate between 50-150 ml per minute. Tests with 7.9% Ammonium persulfate and 0.25% lithium periodate (pH 7.2) with a 2.5% MOYCO alumina content showed 133-142 Angstroms per minute polishing rate, still with tests using the Logitech PM5 polisher (33 rpm, 12 inch IC1000 pad, 2 psi), 3 inch wafers (10,000 A sputtered W), and chemistry/slurry addition rate of 50 to 150 ml/min. The rate of chemical addition had less than 6% effect on the polishing rate between 25-100 ml per minute.

Ammonium Persulfate with KIO₄

Ammonium persulfate can advantageously be combined with KIO₄. A test with 10% Ammonium persulfate added at 90 ml per minute with 5% LOGITECH abrasive, using an IC1000 pad at 2 psi and 33 rpm on a 3″ IWS substrate gave the following surprising results. With no KIO₄, the pH was 7.9 and the polishing rate was 198 Angstroms per minute. But with the addition of 2% KIO₄, the pH declined to 6.9 but the polishing rate increased substantially to 637 Angstroms per minute. Controlled tests, where a 10% Ammonium persulfate, 0.3% KIO₄, and 5% MOYCO abrasive added at 100 and 20 ml per minute, respectively, and using an IC 1000 pad at 33 rpm and 2 psi pressure on a 3″ IWS substrate formed the basis, were performed. The pH of the slurry was varied from 3.1 to 7.5. The polishing rate varied from about 200 at pH 3-4, to 340 at pH 7.5. The Ammonium persulfate concentration can vary from 5 to 15%, and the KIO₄ concentration can vary from about 0.1 to about 5%, preferably from 0.3 to 2%. The pH can be varied from 1-12, preferably from 3-9, depending on the rate of polishing desired.

In some embodiments, it was found that mixing Ammonium persulfate with lithium periodate and with potassium periodate provides extra synergy. With 10% Ammonium persulfate formulations, added at 100 ml per minute with 1% MOYCO alumina abrasive, using an IC1000 pad at 2 psi and 33 rpm on a 3″ IWS substrate, the following results were obtained. With 0.3% K—Li periodates at pH 7.2, the polishing rate was 215 Angstroms per minute. Decreasing the K—Li periodates to 0.2% and the pH to 6.5 reduced the polishing rate to 150-200 Angstroms per minute. Decreasing the K—Li periodates to 0.1% and the pH to 6.5 reduced the polishing rate to 170 Angstroms per minute.

Ammonium Persulfate with KIO₃

Ammonium persulfate can advantageously be combined with KIO₃. A test with 10% Ammonium persulfate added at 90 ml per minute with 5% LOGITECH abrasive, using an IC1000 pad at 2 psi and 33 rpm on a 3″ IWS substrate gave the following surprising results. With no KIO₃, and at a pH of 7.9, the polishing rate was 198 Angstroms per minute. With 5% KIO₃, and at a pH of 7.2 and 7.8, respectively, the polishing rate was 339 and 350 Angstroms per minute, respectively. Lesser concentrations had a lesser effect. For the same conditions, but with 2% KIO₃, and at a pH of 7-7.2, the polishing rate was 193 and 246 Angstroms per minute. The polishing rate remains elevated even at pH 5.8, where the rate was 208 Angstroms per minute.

Another excellent secondary oxidizer is peracetic acid. The secondary oxidizer can, of course be used with any primary oxidizer. In a low pH test 10% Ammonium persulfate with 1% peracetic acid (pH 4.6) added at 90 ml per minute with 5% LOGITECH abrasive slurry added at 20 ml per minute, using an IC1000 pad at 2 psi and 33 rpm on a 3″ IWS substrate, the polishing rate was 325 Angstroms per minute.

Ammonium Persulfate and Imidazole

Ammonium persulfate was tested with numerous other secondary oxidizers. One excellent secondary oxidizer is imidazole. A baseline test with 10% Ammonium persulfate added at 90 ml per minute with 5% LOGITECH abrasive at 20 ml per minute, using an IC1000 pad at 2 psi and 33 rpm on a 3″ IWS substrate gave polishing rates of 105 Angstroms per minute at pH 6 and 198 Angstroms per minute at pH 7.9. In a 10% Ammonium persulfate with 2% imidazole (H 7.4) added at 90 ml per minute with 5% LOGITECH abrasive slurry added at 20 ml per minute, using an IC1000 pad at 2 psi and 33 rpm on a 3″ IWS substrate, the polishing rate was 192 Angstroms per minute. A 10% Ammonium persulfate with 1% imidazole (pH 8.2) added at 90 ml per minute with 5% LOGITECH abrasive slurry added at 20 ml per minute gave a polishing rate of 427 Angstroms per minute. Imidazole at 0.1% and Ammonium persulfate at 10% (pH 7.6-7.7) gave a polishing rate of about 162 Angstroms per minute. Imidazole at 0.1% without Ammonium persulfate exhibited essentially zero polishing rate. At low pH, 0.1% imidazole with 10% ASP had little effect, giving a polishing rate of 70 Angstroms per minute. When mixed with Ammonium persulfate for tungsten substrates, it is beneficial that the quantity of imidazole be between about 0.5% and 4%.

Ammonium Persulfate with Ammonium Lactate

Another secondary oxidizer is an ammonium carboxylate, such as ammonium lactate. In a 10% Ammonium persulfate with 5% ammonium lactate added at 100 ml per minute with 1% MOYCO abrasive slurry, using an IC1000pad at 2 psi and 33 rpm on a 3″ IWS substrate, the polishing rate was 156 Angstroms per minute at pH 4.8 and 217 Angstroms per minute at pH 7.5. Ammonium lactate at 5% without Ammonium persulfate exhibited essentially zero polishing rate, even at pH 8. When mixed with Ammonium persulfate for tungsten substrates, it is beneficial that the quantity of ammonium carboxylate be between about 2% and about 10%.

Ammonium Persulfate with Hydrogen Peroxide

Yet another secondary oxidizer is hydrogen peroxide. Hydrogen peroxide is such an aggressive oxidizer that, when admixed into an Ammonium persulfate-based formulation, the amount of Ammonium persulfate is typically reduced. In tests with no abrasive, using a POLITEX pad at 33 rpm and 2 psi, gave the following results. A 5% Ammonium persulfate and 1% hydrogen peroxide at pH 3.1 gave a polishing rate of 33 Angstroms per minute. A 2% Ammonium persulfate and 2% hydrogen peroxide at pH 3.4 gave a polishing rate of 60 Angstroms per minute. A 2% Ammonium persulfate and 5% hydrogen peroxide at pH 8.5 gave a polishing rate of 186 Angstroms per minute, though this seemed low. A 2% Ammonium persulfate and 2% hydrogen peroxide at pH 7.6 gave a polishing rate of 208 Angstroms per minute.

Ammonium persulfate and hydrogen peroxide in some embodiments benefit from addition of carboxylic acids, especially acids such as citric and oxalic acid that have some chelating capacity. A 2% Ammonium persulfate, 2% hydrogen peroxide, and 1% oxalic acid formulation at pH 7.6 gave a polishing rate of 220 Angstroms per minute.

Hydrogen peroxide can be used as the primary oxidizer also. A test with 5% Ammonium persulfate and 10% hydrogen peroxide at a low pH of 3, added at 20 ml per minute with 5% LOGITECH abrasive at 20 ml per minute, using an IC1000 pad at 2 psi and 33 rpm on a 3′ IWS substrate gave polishing rates of 169-198 Angstroms per minute.

Ammonium Persulfate with Other Oxidizers

A test with 10% Ammonium persulfate and 5% NH₄HF₂ at a low pH of 5.1, added at 90 ml per minute with 5% LOGITECH abrasive at 20 ml per minute, using an IC1000 pad at 2 psi and 33 rpm on a 3″ IWS substrate gave a polishing rate of 88 Angstroms per minute.

A test with 10% Ammonium persulfate and 1% peracetic acid at a low pH of 4.6, added at 90 ml per minute with 5% LOGITECH abrasive at 20 ml per minute, using an IC1000 pad at 2 psi and 33 rpm on a 3″ IWS substrate gave a polishing rate of 325 Angstroms per minute.

Various nitrates can be beneficially added to a primary oxidizer. A test with 10% Ammonium persulfate and 10% calcium nitrate at a low pH of 5.6, added at 90 ml per minute with 5% LOGITECH abrasive at 20 ml per minute, using an IC1000 pad at 2 psi and 33 rpm on a 3″ IWS substrate gave a polishing rate of 86 Angstroms per minute.

A test with 10% Ammonium persulfate and 5% lithium nitrate at a low pH of 5.1, added at 90 ml per minute with 5% LOGITECH abrasive at 20 ml per minute, using an IC1000 pad at 2 psi and 33 rpm on a 3″ IWS substrate gave a polishing rate of 111 Angstroms per minute. Increasing the pH to 7 increased the polishing rate only modestly.

A test with 10% Ammonium persulfate and 1% ammonium tungsate at a pH of 6.6 to 7, added at 90 ml per minute with 5% LOGITECH abrasive at 20 ml per minute, using an IC1000 pad at 2 psi and 33 rpm on a 3″ IWS substrate gave a polishing rate of about 90 Angstroms per minute.

### Example 4

### Tungsten Substrate with Other Oxidizers

Periodic Acid

Periodic acid is an excellent oxidizer for tungsten substrates. While periodic acid may be admixed with Ammonium persulfate as discussed above, it is also a particularly good primary oxidizer. Tungsten polishing using PIA is preferably done at pH 7 to 9. Citric acid and other chelators at this pH range provide excellent polishing characteristics.

Numerous tests were performed using periodic acid formulations added at 50 and 100 ml per minute to with MOYCO abrasive slurries added, using IC1000 pads at 33 rpm with a force of 2 psi on 3″ IWS substrates. Formulations with 1% periodic acid at pH 3.6 with 2.5% abrasive slurry gave etch rates of about 120 Angstroms per minute. Formulations with 2% periodic acid at pH 1.5 with 1% abrasive slurry gave etch rates of about 130 Angstroms per minute. Formulations with 2% periodic acid at pH 2 with 1% abrasive slurry gave etch rates of about 300 Angstroms per minute. Formulations with 2% periodic acid at pH 2.5 with 2.5% abrasive slurry gave etch rates of about 300 Angstroms per minute. Formulations with 2% periodic acid at pH 6.8 with 2.5% abrasive slurry gave etch rates of about 420 Angstroms per minute.

Using higher pressures gave very high polishing rates. Numerous tests were performed using 2% periodic acid formulations at pH 6 with MOYCO abrasive slurries added, using IC1000 pads on 8″ IWS substrates. Tests at 40 rpm with a force of 5 psi gave polishing rates of about 2600 Angstroms per minute. Tests at 50 rpm with a force of 5 psi gave polishing rates of about 3100 Angstroms per minute. Tests at 50 rpm with a force of7 psi gave polishing rates of about 3660 Angstroms per minute.

Periodic acid formulations, containing from 0.5 to 8%, preferably from about 1% to about 3% periodic acid, is preferred for tungsten substrates. Of course, acids, other primary and secondary oxidizers, chelators, and pH control compounds are advantageously included.

OXONE and Other Oxidizers

Slurry tests using on 3″ IWS substrates using as the primary oxidizer OXONE at 1-2% showed poor polishing rates. Slurry tests using on 3″ IWS substrates using as the primary oxidizer lithium nitrate at 5-10% showed modest, i.e., about 100 Angstroms per minute, polishing rates. Slurry tests using on 3″ IWS substrates using as the primary oxidizer calcium nitrate at 10% showed poor polishing rates. Slurry tests using on 3″ IWS substrates using as the a primary oxidizer aluminum nitrate at 10% showed poor polishing rates. Slurry tests using on 3″ IWS substrates using as the primary oxidizer Ce(NH₄)₂NO₃ at 5% showed poor polishing rates. Slurry tests using on 3″ IWS substrates using as the primary oxidizer Bi(NO₃)₂ at 5% showed poor polishing rates.

Hydroxylamine

Slurry tests using 10% hydroxylamine formulations at pH 9.4 showed almost no polishing. Adding various secondary oxidizers, such as catechol, and various carboxylic acids had very limited effect.

A test with 10% hydroxylamine and 10% hydrogen peroxide at pH 8.7, added at 20 ml per minute to 20 ml per minute of 5% LOGITECH abrasive, using POLITEX pads at 33 rpm at 2 psi force on 3″ IWS substrate, gave a polishing rate of 730 Angstroms per minute.

Adding a carboxylic acid, especially citric acid, was also found to be beneficial. A test with 10% hydroxylamine and 5% each of citric acid and hydrogen peroxide at pH 8. 1, added at 20 ml per minute to 20 ml per minute of 5% LOGITECH abrasive, using POLITEX pads at 33 rpm at 2 psi force on 3″ IWS substrate, gave a polishing rate of 240 Angstroms per minute. A test with 10% hydroxylamine and 5% each of citric acid and hydrogen peroxide at pH 7.5, added at 20 ml per minute to 20 ml per minute of 5% LOGITECH abrasive, using POLITEX pads at 33 rpm at 2 psi force on 3″ IWS substrate, gave a polishing rate of 380 Angstroms per minute. A test with 10% hydroxylamine and 10% each of citric acid and hydrogen peroxide at pH 7.4, added at 20 ml per minute to 20 ml per minute of 5% LOGITECH abrasive, using POLITEX pads at 33 rpm at 2 psi force on 3″ IWS substrate, gave a polishing rate of 430 Angstroms per minute.

The Hydroxylamine/Citric acid/Hydrogen peroxide formulations, containing about 3% to about 12% of each ingredient, performs well on tungsten when the pH is between about 4 and about 9.

Hydroxylamine Nitrate

Hydroxylamine nitrate as the primary oxidizer did not give acceptable polishing rates on tungsten.

Hydrogen Peroxide

Hydrogen Peroxide in slurry formulations containing about 10% and at pH 3.4 provided polishing rates on tungsten of between 300 and 550 Angstroms per minute. Formulations containing either 5% or 15% hydrogen peroxide did not perform as well. A preferred formulation therefore contains between about 7% and 13% hydrogen peroxide.

Urea peroxide is a secondary oxidizer that can be paired with any primary oxidizer. However, a 2-4% solution did not give polishing rates above 83 Angstroms per minute with tungsten.

Peracetic Acid

Peracetic acid is an excellent secondary oxidizer. A 3.5% solution added at about 90 ml per minute to a 2% slurry of MOYCO MC abrasive added at 20 ml per minute showed increasing polishing rates with increasing pH. At pH 1.5, the polishing rate was 36 Angstroms per minute. At pH 7.5 the polishing rate was 166 Angstroms per minute.

Sodium Percarbonate

Sodium Percarbonate is an excellent primary and secondary oxidizer. A 5% solution at pH 10.4 added at about 20 ml per minute with a POLITEX pad at 33 rpm and applying 2 psi force to a 3″ IWS substrate gave a polishing rate of 168 Angstroms per minute. Sodium perborate, however, performed poorly, as did sodium hypochlorite.

KIO₄

KIO₄ is an excellent oxidizer. A test with 0.2% KIO₄ at pH 7.9, added at 90 ml per minute to 20 ml per minute of 5% LOGITECH abrasive, using IC1000 pads at 33 rpm at 2 psi force on 3″ IWS substrate, gave a polishing rate of 142 Angstroms per minute.

KIO₃

KIO₃ is an excellent oxidizer. A test with 2% KIO₃ at pH 7. 1, added at 90 ml per minute to 20 ml per minute of 5% LOGITECH abrasive, using IC1000 pads at 33 rpm at 2 psi force on 3″ IWS substrate, gave a polishing rate of 193 Angstroms per minute.

Fe(NO₃)₃

Current CMP processes for W are based on acid chemistries comprising ferric nitrate or hydrogen peroxide. Because the tungstate anion has a maximum solubility at pH values greater than 6, an alternative W polishing approach is to oxidize the W metal with an oxidizing agent under basic conditions. Fe(NO₃)₃ is an excellent oxidizer, though it can only be stable at low pH and though it provides undesired iron atoms to the formulation.

A test with 10% Fe(NO₃)₃ at pH 1.2, added at 20 ml per minute to 20 ml per minute of 5% LOGITECH abrasive, using POLITEX pads at 33 rpm at 2 psi force on 3″ IWS substrate, gave a polishing rate of over 1000 Angstroms per minute.

A test with 5% Fe(NO₃)₃ at pH 1.2, added at 20 ml per minute to 20 ml per minute of 5% LOGITECH abrasive, using POLITEX pads at 33 rpm at 2 psi force on 3″ IWS substrate, gave a polishing rate of 1690 Angstroms per minute.

A test with 7% Fe(NO₃)₃ at pH 1, added at 100 ml per minute to a 2.5% MOYCO abrasive, using IC1000 pads at 33 rpm at 2 psi force on 3″ IWS substrate, gave a polishing rate of over about 200 Angstroms per minute. When used with no abrasive, but just a POLITEX pad, the polishing rate is below 100 Angstroms per minute.

Ammonium Bifluoride

NH₄HF₂

NH₄HF₂, an excellent fluoridizer, gave only 40 to 90 Angstroms per minute polishing rates when used at pH 2-5, concentrations of 1% to 5%, with or without abrasives. Addition of a small amount of hydrogen peroxide and of surfactants, less than 1% of each, improved the polishing rate a small amount.

Others

Secondary oxidizers such as ammonium lactate at 5% and at pH 4-8, 20% periodic acid at pH 12, Gluconic acid at 20% and at pH 2.1, ammonium phosphate at 5% and at pH 4-7, and ammonium hydroxide at 10% and at pH 12.6, showed poor polishing rates.

### Example 5

Oxide Substrate

Hydroxylamine, an excellent oxidizer for copper and other substrates, can also be used in a reductive capacity to polish metal oxides. The formulation is beneficially at least 9, preferably between 9 and 12, more preferably between 10 and 11. A formulation of 10% hydroxylamine was prepared and adjusted to pH 10.6. This formulation was added at 50 ml per minute to an 8% slurry of MOY SC abrasive, and the formulation was applied to a 3″ BPSG substrate with a IC 1000 pad at 33 rpm and 2 psi pressure. The polishing rate was greater than 380 Angstroms per minute. The formulation was allowed to age 21 days. It was found to have a pH of 10.7, and the polishing rate was above 340 Angstroms per minute.

A formulation of 10% hydroxylamine was prepared and adjusted to pH 10.6. This formulation was added at 50 ml per minute to an 8% slurry of MOY SC abrasive, and the formulation was applied to a 3″ BPSG substrate with a POLITEX pad at 33 rpm and 2 psi pressure. The polishing rate was 558 Angstroms per minute.

Hydroxylamine nitrate at 0.5% with 0.02% Hydroxylamine at pH 4 was found to have a polishing rate of only 37 Angstroms per minute when added at 50 ml per minute to an 2.5% slurry of MOY SC abrasive and the formulation applied to a 3″ BPSG substrate with a IC 1000 pad at 33 rpm and 2 psi pressure.

Periodic acid at 3% and pH 6.5 was found to have a polishing rate of only 9 Angstroms per minute when added to a 2.5% slurry of MOY SC abrasive and the formulation applied to a 3″ BPSG substrate with a IC 1000 pad at 33 rpm and 2 psi pressure.

High polishing rates, for example greater than 400 Angstroms per minute, were observer with potassium hydroxide and with ammonium biflouride in water.

### Example 6

### Aluminum Substrate

Ammonium Persulfate

A variety of Ammonium persulfate formulations were tested on aluminum wafers.

Tests were run with Ammonium persulfate compositions of 2%, added at 50 ml per minute, using a MoycoMC™ 1% formulation at 33 RPM at 2 psi force with a IC1000™ pad on a 3 inch IWS wafer. The polishing rate at pH 4 was 425 A/minute, while at pH 2 the rate was only 365 A/minute.

The Ammonium persulfate composition is preferably between about about 0.5 to 10%, preferably between 0.5 to 6%, more preferably between about 1 to 4%, and most preferably about 2%. The MoycoMC™ formulation is preferably between about 0.1 to 4%, and more preferably about 1%.

Testing was also performed on 3″ IWS aluminum wafers with Politex™ pads at about 2 psi at 33 RPM. In a first formulation, the slurry included 20 ml/minute of 5% Moyco™ abrasive in 90 ml/minute 5% Ammonium persulfate. The pH was held at 5.9. The polishing rate was a very low 1 A/minute. This result was confirmed in a duplicate test.

In a second formulation, the slurry included 20 ml/minute of 5% alumina abrasive in 20 ml/minute 5% Ammonium persulfate. The pH was held at 4.5. The polishing rate on a 3″ EMF substrate was a very high 4280 A/minute.

According to the first formulation, the Ammonium persulfate is delivered at a flow rate of between about 50 to 150 ml/min., more preferably between about 80 to 120 ml/min., and most preferably about 90 ml/min. According to the second formulation, the Ammonium persulfate is delivered at a flow rate of between about 5 to 50 ml/min., more preferably between about 10 to 40 ml/min., and most preferably about 20 ml/min. The MoycoMC™ abrasive formulation is preferably between about 0.5 to 10 wt. %, more preferably between about 2 to 8 wt. %, and most preferably about 5 wt. %, and is delivered at a flow rate of between about 5 to 50 ml/min., more preferably between about 10 to 40 ml/min., and most preferably about 20 ml/min. The alumina formulation is preferably between about 0.5 to 10%, more preferably between about 2 to 8%, and most preferably about 5%, and is delivered at a flow rate of between about 5 to 50 ml/min., more preferably between about 10 to 40 ml/min., and most preferably about 20 ml/min.

A 5% Ammonium persulfate solution at pH of 3.4 that was added at 20 ml/minute gave an aluminum polishing rate of 105 A/minute on a 3 inch IWS wafer, polished with a Polytex™ pad at 33 RPM at 2 psi. A 10% Ammonium persulfate solution, with all other parameters remaining the same, gave a polishing rate of 23 A/minute on a 3 inch EMF wafer

Certain organic acids can enhance/retard polishing rates. In addition to citric acid, oxalic acid and gluconic acid were tested here. Oxalic acid added at 1% to a 10% Ammonium persulfate solution at 20 ml and at pH 1.4 using a Polytex™ pad on a 3 inch IWS wafer at 33 RPM and 2 psi, gave a polishing rate of 23 A/minute. Gluconic acid added at 20% to a 10% Ammonium persulfate solution at 20 ml and at pH 1.4 using a Polytex™ pad on a 3 inch IWS wafer at 33 RPM and 2 psi, gave a polishing rate of only 6.8 A/minute.

The Ammonium persulfate concentration is preferably between about 2 to 20%, more preferably between about 5 to 15%, and most preferably about 10%. The oxalic acid is added to the Ammonium persulfate at a concentration of between about 0.1 and 5%, and more preferably about 1%. The gluconic acid is added to the Ammonium persulfate at a concentration of between about 1 to 50%, more preferably between about 10 to 30%, and most preferably about 20%. The slurry is delivered at a flow rate of between about 5 to 50 ml/min., more preferably between about 10 to 40 ml/min., and most preferably about 20 ml/min.

Low concentrations of Ammonium persulfate can still provide reasonable aluminum polishing rates if other parameters are adjusted. A 1% Ammonium persulfate solution added at 90 ml/min at a pH of 3.5 with a 5% Silica ST™ slurry added at 20 ml/minute using a Polytex™ pad on a 3 inch IWS wafer at 33 RPM and 2 psi gave a polishing rate of 225 A/minute.

This Ammonium persulfate composition is preferably between about 0.5 to 5%, more preferably between about 1 to 4%, and most preferably about 1%. The silica is preferably between about 0.5 to 10%, more preferably between about 2 to 8%, and most preferably about 5%, and the combined slurry is delivered at a flow rate of between about 5 to 50 ml/min., more preferably between about 10 to 40 ml/min., and most preferably about 20 m/min.

Additional tests were conducted with 100% Ammonium persulfate solutions dispensed at 20 ml/min. Using an alumina abrasive dispensed at 20 ml/min., a 1918 A/min. polish rate was obtained for a 3 inch EMF wafer on a Politex pad; and a 1646 A/min. polish rate was obtained for a 3 inch IWS wafer using a polyurethane pad. In comparison, using a Sytron abrasive dispensed at 20 ml/min., a polish rate of 303 A/min. was obtained for a 3 inch EMF wafer on a Politex pad.

Ammonium Salts

Aluminum was polished with different ammonium salt solutions added at 20 m/min. using a Polytex™ pad on a 3 inch IWS wafer at 33 RPM and 2 psi. A 5% NH₄OH solution (pH 12) gave a polishing rate of 3000 A/min.

A 10% NH₄Cl solution (pH 4.5) gave a polishing rate of 25 A/min.

Furthermore, a 5% NH₄HF₂ solution (pH<2) gave a polishing rate greater than 4000 A/min. while a 0.2% NH₄HF₂ solution gave a polish rate of 1200 A/min.

It can be seen that by choosing the ammonia salts reasonably high polishing rates can be obtained at a number of pH ranges. The ammonia salt solutions can be enhanced by the addition of acids, chelators, oxidizers, and the like.

Hydroxylamine

The use of hydroxylamine-based formulations on aluminum substrates can provide a range of polishing rates of aluminum.

At pH 10, 5% and 10% formulations of Hydroxylamine had between 2 and 25 Angstrom per minute polishing rates when applied at 20 ml per minute to a POLITEX pad using 2 psi pressure on 3″ IWS and 3″ EMF substrates.

Hydroxylamine Nitrate

A variety of 5-10% hydroxylamine nitrate formulations adjusted to pH 2.9-4 showed less than 5 Angstroms per minute polishing rate when applied with 2 psi pressure and at 10-33 rpm on 3″ IWS aluminum substrates.

Water

Water when applied with alumina slurries at about 20 ml per minute each showed surprisingly high polishing rates on 3″ EMF and IWS aluminum substrates, between about 1600 and about 1900 Angstroms per minute, when applied at 2 psi with a POLITEX or an Polyurethane pad. With SYTRON 4% slurry added with water, the POLITEX pad showed a polishing rate of about 300 Angstroms per minute.

We claim:

1. A method for chemical mechanical polishing of tungsten comprising:
providing a semiconductor substrate comprising on one face tungsten and a dielectric material;
providing a chemical mechanical polishing composition comprising between about 2% and about 15% ammonium persulfate, between about 0.1% and about 10% of a secondary oxidizer, a pH adjusting compound to adjust the pH of the composition, and optionally an abrasive, wherein the pH of the composition is between about 6.5 to about 12;
movably contacting the substrate face with a pad exerting between about 0.1 and about 9 psi pressure on the substrate and with the composition under conditions that tungsten is removed at a rate different than the removal of the dielectric material.

2. The process of claim 1 wherein the secondary oxidizer comprises potassium peroxymonosulfate, peroxymonosulfuric acid, imidazole, malonic acid, or malonamide.

3. The process of claim 1 wherein the chemical mechanical polishing composition comprises at least one of potassium iodate, potassium periodate, or lithium periodate.

4. The process of claim 1, wherein the chemical mechanical composition comprises periodic acid, peracetic acid, oxalic acid, citric acid, lactic acid, NH₄HF₂, or a mixture thereof.

5. The process of claim 1 wherein the secondary oxidizer comprises hydrogen peroxide, a perborate, a peroxhydrate, or a urea hydrogen peroxide complex.

6. The process of claim 1 wherein the chemical mechanical polishing composition additionally comprises an organic acid selected from the group consisting of gluconic, malonic acid, lactic acid, succinic acid, tartaric acid, citric acid, oxalic acid, or salts thereof.

7. The process of claim 1 further comprising a second polishing operation comprising the steps of:
providing a second chemical mechanical polishing composition comprising an oxidizer, a pH adjusting compound to adjust the pH of the composition, and optionally an abrasive, wherein the pH of the composition is between about 3 to about 12;
movably contacting the substrate face with a pad exerting between about 0.1 and about 9 psi pressure on the substrate and with the second composition under conditions that tungsten is removed at a rate different than the removal of the dielectric material.

8. The process of claim 7 wherein the second chemical mechanical polishing composition comprises ammonium persulfate, a pH adjusting compound to adjust the pH of the composition, and optionally an abrasive, wherein the pH of the composition is between about 3 to about 12.

9. A method for chemical mechanical polishing of tungsten comprising:
providing a semiconductor substrate comprising on one face tungsten and a dielectric material;
providing a chemical mechanical polishing composition comprising between about 0.5% and about 10% periodic acid, between about 0.1% and about 10% of a secondary oxidizer, a pH adjusting compound to adjust the pH of the composition, and optionally an abrasive, wherein the pH of the composition is between about 4 to about 12;
movably contacting the substrate face with a pad exerting between about 0.1 and about 9 psi pressure on the substrate and with the composition under conditions that tungsten is removed at a rate different than the removal of the dielectric material.

10. The process of claim 9 wherein the secondary oxidizer comprises potassium peroxymonosulfate, imidazole, malonic acid, or malonamide.

11. The process of claim 9 wherein the chemical mechanical polishing composition comprises at least one of potassium iodate, potassium periodate, or lithium periodate.

12. The process of claim 9 wherein the chemical mechanical composition comprises ammonium persulfate, peracetic acid, oxalic acid, NH₄HF₂, or a mixture thereof.

13. The process of claim 9 wherein the secondary oxidizer comprises hydrogen peroxide, a perborate, a peroxhydrate, or a urea hydrogen peroxide complex.

14. The process of claim 9 wherein the chemical mechanical polishing composition additionally comprises an organic acid selected from the group consisting of gluconic, malonic acid, lactic acid, succinic acid, tartaric acid, citric acid, oxalic acid, or salts thereof.

15. The process of claim 9 further comprising a second polishing operation comprising the steps of:
providing a second chemical mechanical polishing composition comprising an oxidizer, a the pH adjusting compound to adjust the pH of the composition, and optionally an abrasive, wherein the pH of the composition is between about 3 to about 12;
movably contacting the substrate face with a pad exerting between about 0.1 and about 9 psi pressure on the substrate and with the second composition under conditions that tungsten is removed at a rate different than the removal of the dielectric material.

16. The process of claim 9, wherein the second chemical mechanical polishing composition comprises 0.5% and about 10% periodic acid, a pH adjusting compound to adjust the pH of the composition, and optionally an abrasive, wherein the pH of the composition is between about 3 to about 12.

17. A method for chemical mechanical polishing of copper comprising:
providing a semiconductor substrate comprising on one face copper and a dielectric material;
providing a chemical mechanical polishing composition comprising between about 1% and about 20% hydroxylamine, hydroxylamine sulfate, hydroxylamine nitrate, or mixture thereof, between about 0.1% and about 10% of a carboxylic acid, a pH adjusting compound to adjust the pH of the composition, and optionally an abrasive, wherein the pH of the composition is between about 3 to about 12;
movably contacting the substrate face with a pad exerting between about 0.1 and about 9 psi pressure on the substrate and with the composition under conditions that copper is removed at a rate different than the removal of the dielectric material.

18. The process of claim 17 wherein the chemical mechanical polishing composition comprises potassium peroxymonosulfate, imidazole, malonic acid, or malonamide, and wherein the second material is a dielectric material.

19. The process of claim 17 wherein the chemical mechanical polishing composition comprises at least one of potassium iodate, potassium periodate, or lithium periodate.

20. The process of claim 17 wherein the chemical mechanical composition comprises periodic acid, peracetic acid, oxalic acid, NH₄HF₂, or a mixture thereof.

21. The process of claim 17 wherein the secondary oxidizer comprises hydrogen peroxide, a perborate, a peroxhydrate, or a urea hydrogen peroxide complex.

22. The process of claim 17 wherein the chemical mechanical polishing composition additionally comprises an organic acid selected from the group consisting of gluconic, malonic acid, lactic acid, succinic acid, tartaric acid, citric acid, oxalic acid, or salts thereof.

23. The process of claim 17 further comprising a second polishing operation comprising the steps of:
providing a second chemical mechanical polishing composition comprising an oxidizer, a pH adjusting compound to adjust the pH of the composition, and optionally an abrasive, wherein the pH of the composition is between about 3 to about 12;
movably contacting the substrate face with a pad exerting between about 0.1 and about 9 psi pressure on the substrate and with the second composition under conditions that copper is removed at a rate different than the removal of the dielectric material.

24. The process of claim 17 wherein the second chemical mechanical polishing composition comprises hydroxylamine or a salt thereof, a pH adjusting compound to adjust the pH of the composition, and optionally an abrasive, wherein the pH of the composition is between about 3 to about 12.

25. A method for chemical mechanical polishing of aluminum comprising:
providing a semiconductor substrate comprising on one face aluminum and a dielectric material;
providing a chemical mechanical polishing composition comprising between about 2% and about 12% ammonium persulfate, a pH adjusting compound to adjust the pH of the composition, and optionally an abrasive, wherein the pH of the composition is between about 2 to about 8;
movably contacting the substrate face with a pad exerting between about 0.1 and about 9 psi pressure on the substrate and with the composition under conditions that aluminum is removed at a rate different than the removal of the dielectric material.

26. The process of claim 25 wherein the chemical mechanical polishing composition comprises potassium peroxymonosulfate, peroxymonosulfuric acid, imidazole, malonic acid, or mixture thereof.

27. The process of claim 25 wherein the chemical mechanical polishing composition comprises at least one of potassium iodate, potassium periodate, or lithium periodate.

28. The process of claim 25, wherein the chemical mechanical composition comprises periodic acid, peracetic acid, oxalic acid, citric acid, lactic acid, NH₄HF₂, or a mixture thereof.

29. The process of claim 25 wherein the chemical mechanical polishing composition comprises hydrogen peroxide, a perborate, a peroxhydrate, or a urea hydrogen peroxide complex.

30. The process of claim 25 wherein the chemical mechanical polishing composition additionally comprises an organic acid selected from the group consisting of gluconic, malonic acid, lactic acid, succinic acid, tartaric acid, citric acid, oxalic acid, or salts thereof.

31. The process of claim 25 further comprising a second polishing operation comprising the steps of:
providing a second chemical mechanical polishing composition comprising an oxidizer, a pH adjusting compound to adjust the pH of the composition, and optionally an abrasive, wherein the pH of the composition is between about 3 to about 12;
movably contacting the substrate face with a pad exerting between about 0.1 and about 9 psi pressure on the substrate and with the second composition under conditions that alumina is removed at a rate different than the removal of the dielectric material.

32. The process of claim 25 wherein the second chemical mechanical polishing composition comprises ammonium persulfate, a pH adjusting compound to adjust the pH of the composition, and optionally an abrasive, wherein the pH of the composition is between about 3 to about 12.

33. A method for chemical mechanical polishing of a substrate comprising:
providing a semiconductor substrate comprising on one face a metal and a dielectric material;
providing a chemical mechanical polishing composition comprising between about 0.1% and about 10% of ammonium hydroxide, NH₄HF₂, peracetic acid, or mixture thereof, a pH adjusting compound to adjust the pH of the composition, and optionally an abrasive, wherein the pH of the composition is between about 2 to about 13;
movably contacting the substrate face with a pad exerting between about 0.1 and about 9 psi pressure on the substrate and with the composition under conditions that metal is removed at a rate different than the removal of the dielectric material.

34. The process of claim 33 wherein the chemical mechanical polishing composition comprises potassium peroxymonosulfate, peroxymonosulfuric acid, imidazole, malonic acid, or malonamide.

35. The process of claim 33 wherein the chemical mechanical polishing composition comprises at least one of potassium iodate, potassium periodate, or lithium periodate.

36. The process of claim 33, wherein the chemical mechanical composition comprises periodic acid, peracetic acid, oxalic acid, citric acid, lactic acid, or a mixture thereof.

37. The process of claim 33 wherein the chemical mechanical polishing composition comprises hydrogen peroxide, a perborate, a peroxhydrate, or a urea hydrogen peroxide complex.

38. The process of claim 33 wherein the chemical mechanical polishing composition additionally comprises an organic acid selected from the group consisting of gluconic, malonic acid, lactic acid, succinic acid, tartaric acid, citric acid, oxalic acid, or salts thereof.

39. The process of claim 33 further comprising a second polishing operation comprising the steps of:
providing a second chemical mechanical polishing composition comprising an oxidizer, a pH adjusting compound to adjust the pH of the composition, and optionally an abrasive, wherein the pH of the composition is between about 3 to about 12;
movably contacting the substrate face with a pad exerting between about 0.1 and about 9 psi pressure on the substrate and with the second composition under conditions that the metal is removed at a rate different than the removal of the dielectric material.

40. A method for chemical mechanical polishing of copper comprising:
providing a semiconductor substrate comprising on one face copper and a dielectric material;
providing a chemical mechanical polishing composition comprising between about 0.1% and about 10% ammonium persulfate, at least one of a secondary oxidizer, an organic acid, or a chelating agent, a pH adjusting compound to adjust the pH of the composition, and optionally an abrasive, wherein the pH of the composition is between about 3 to about 8;
movably contacting the substrate face with a pad exerting between about 0.1 and about 9 psi pressure on the tungsten substrate and with the composition under conditions that tungsten is removed at a rate different than the removal of the dielectric material.

41. The process of claim 40 wherein the secondary oxidizer comprises potassium peroxymonosulfate, imidazole, malonic acid, potassium iodate, potassium periodate, lithium periodate, or malonamide, periodic acid, oxalic acid, and wherein the second material is a dielectric material.

42. The process of claim 41 wherein the chemical mechanical polishing composition additionally comprises an organic acid selected from the group consisting of gluconic, malonic acid, lactic acid, succinic acid, tartaric acid, citric acid, or salts thereof.

43. A method for chemical mechanical polishing of tungsten comprising:
providing a semiconductor substrate comprising on one face tungsten and a dielectric material;
providing a chemical mechanical polishing composition comprising between about 2% and about 20% hydroxylamine, between about 0.1% and about 10% of a secondary oxidizer, a pH adjusting compound to adjust the pH of the composition, and optionally an abrasive, wherein the pH of the composition is between about 7 to about 12;
movably contacting the substrate face with a pad exerting between about 0.1 and about 9 psi pressure on the substrate and with the composition under conditions that tungsten is removed at a rate different than the removal of the dielectric material.

44. The process of claim 43 wherein the secondary oxidizer comprises potassium peroxymonosulfate, peroxymonosulfuric acid, imidazole, malonic acid, or malonamide.

45. The process of claim 43 wherein the chemical mechanical polishing composition comprises at least one of potassium iodate, periodic acid, peracetic acid, potassium periodate, NH₄HF₂, or lithium periodate.

46. The process of claim 43 wherein the secondary oxidizer comprises hydrogen peroxide, a perborate, a peroxhydrate, or a urea hydrogen peroxide complex.

47. The process of claim 43 wherein the chemical mechanical polishing composition additionally comprises an organic acid selected from the group consisting of gluconic, malonic acid, lactic acid, succinic acid, tartaric acid, citric acid, oxalic acid, citric acid, or salts thereof.
